(19) United States
(12) Patent Application Publication
(10) Pub. No.: US 2013/0082382 A1
(43) Pub. Date: Apr. 4, 2013

(54) SEMICONDUCTOR DEVICE

(71) Applicant: Elpida Memory, Inc., Tokyo (JP)

(72) Inventor: Koji TORII, Tokyo (JP)

(73) Assignee: ELPIDA MEMORY, INC., Tokyo (JP)

(21) Appl. No.: 13/630,593

(22) Filed: Sep. 28, 2012

(30) Foreign Application Priority Data
Sep. 29, 2011 (JP) 2011-214473

(51) Int. Cl. H01L 23/485; H01L 25/03

(52) U.S. Cl. 257/737; 257/777; 257/E25.002; 257/E23.021

(57) ABSTRACT

First and second sub-bumps are provided on both surfaces of each substrate along with a usual bump structure (first and second main bumps), and at least one of the first and second sub-bumps is made greater in height than the first and second main bumps, so that the sub-bumps come into contact with one another earlier than the main bumps at the time of joining semiconductor chips, thereby securing margins of joint among the main bumps and suppressing the thin-filming of a layer, such as a solder layer, to be fluidized by heating.

### BACKGROUND OF THE INVENTION

1. Field of the Invention

The present invention relates to a semiconductor device, and more particularly, to a semiconductor device provided with an electrode penetrating through a substrate.

2. Description of the Related Art

Along with the functional upgrading and the diversification of semiconductor devices, there has recently been proposed a semiconductor device integrated by vertically stacking a plurality of semiconductor chips. Such a semiconductor device is configured to achieve electrical conduction between respective semiconductor chips by an electrode penetrating through the substrate of each semiconductor chip. The electrode penetrating through the substrate is so-called a through silicon via (TSV).

For example, JP2010-272737A discloses a method of connecting a plurality of semiconductor chips including TSVs. Bumps are formed on each TSV as connecting terminals on both sides of a semiconductor chip. The bumps include a front bump formed on one surface (front surface) on which semiconductor elements are formed and a rear bump formed on another surface (rear surface). Electrical conduction between semiconductor chips is ensured by joining a front bump of one semiconductor chip and a rear bump of another semiconductor chip to each other with solder.

FIG. 1 is a schematic view of semiconductor device 100 configured by stacking a plurality of semiconductor chips. In semiconductor device 100 illustrated in FIG. 1, base bumps 102 are formed on printed-wiring board 101. Each TSV 103a of a lowermost-layer semiconductor chip (interface chip 103, here) is connected to each base bump 102. First chip 104, second chip 105, third chip 106, and fourth chip 107 are connected in sequence onto interface chip 103 by TSVs 104a, 105a, 106a, and 107a, respectively. Solder balls 108 used to electrically connect semiconductor device 100 to a desired circuit board are provided on a lower portion of printed-wiring board 101. For example, core chips provided with memory cell arrays and logic circuits are applied to the first to fourth chips and a driving part is provided in interface chip 103. Underfill resin, though not illustrated, is filled in a gap between respective chips. In addition, a protective film for covering the entire range of the semiconductor device being fabricated is formed, thereby configuring semiconductor device 100. Note that FIG. 1 is created by the present inventors, in order to describe objects of the present invention, and is not the related art itself.

FIG. 2 illustrates a method of joining semiconductor chips. FIG. 2 is an enlarged view of the part circled by a dashed line in FIG. 1. The front surface side of TSV 104a of first chip 104 includes interconnect layers 109 constituting part of TSV 104a and front bump 112 connected to interconnect layers 109. Front bump 112 includes first metal bump 110 connected to the upper interconnect layer 109 and first metal joining layer 111 formed on a surface of the first metal bump 110. On the other hand, rear bump 115 composed of second metal bump 113 formed integrally with a metal plug constituting part of TSV 105a and second metal joining layer 114 formed on a surface of the second metal bump 113 is provided on the rear surface of second chip 105. First metal joining layer 111 is composed of a Ni/Au laminated film, and second metal joining layer 114 is composed of a solder layer, such as a Sn—Ag alloy layer. A solder reflow treatment is applied in advance to second metal joining layer 114 which is a solder layer, so that a middle portion thereof convexly upheaves. In order to join front bump 112 of first chip 104 and rear bump 115 of second chip 105, the bumps are heat-treated under a predetermined pressure to reflow second metal joining layer 114 composed of a solder layer. Consequently, first metal joining layer 111 and second metal joining layer 114 are joined to each other. At this time, reflowed second metal joining layer 114 is partially extruded out of a joined interface to form side drop 116. That is, as the result of a portion of second metal joining layer 114 at the joined interface transforming into a thin film, Au of first metal joining layer 111 becomes liable to segregation at the interface. This may decrease joint strength and induce bump cracks. The amount of segregated Au increases in particular and cracks occur if thermal stress caused by a reliability test or the like is applied. Thus, there arises the phenomenon that interfacial resistance increases. In addition, a previous solder reflow process may not be fully carried out in some cases for reasons of process steps. The amount of side drop increases if a solder reflow process is not carried out, and therefore, thin-filming progresses further.

### SUMMARY

The present inventor has found a structure in which the thin-filming of layers, such as a solder layer, which are fluidized by heating is suppressed by providing sub-bumps along with a usual bump structure (main bumps), so that the sub-bumps come into contact with one another earlier than the main bumps at the time of joining semiconductor chips, thereby securing margins of joint between the main bumps.

That is, according to one exemplary embodiment of the present invention, there is provided a semiconductor device including:

a substrate including a semiconductor substrate;

a first main bump and a first sub-bump formed over the substrate to protrude from a first surface of the substrate; and

a second main bump and a second sub-bump formed over the substrate to protrude from a second surface of the substrate,

the first main bump and the second main bump being electrically connected to each other through at least a plug penetrating through the semiconductor substrate, wherein the semiconductor device has at least one of a difference between the height of the first sub-bump from the first surface of the substrate and the height of the first main bump from the first surface of the substrate and a difference between the height of the second sub-bump from the second surface of the substrate and the height of the second main bump from the second surface of the substrate.

According to another exemplary embodiment of the present invention, there is provided a semiconductor device provided with an electrode penetrating through a substrate, the electrode including:

a main electrode provided with a first main bump protruded from a first surface of the substrate, and a second main bump protruded from a second surface of the substrate to constitute a current pathway; and

a sub-electrode provided with a first sub-bump protruded from the first surface of the substrate and a second sub-bump protruded from the second surface of the substrate,

wherein the length of the sub-electrode, including the first sub-bump and the second sub-bump, in a substrate thickness direction is greater than the length of the main electrode, including the first main bump and the second main bump.

According to yet another exemplary embodiment of the present invention, there is provided a semiconductor device including:

a plurality of semiconductor chips stacked to each other,

a first main bump and a first sub-bump protruded from a first surface of each of semiconductor chips; and

a second main bump and a second sub-bump protruded from a second surface of each of the semiconductor chips, wherein

the first main bump and the second main bump being electrically connected to each other through at least a plug penetrating through a semiconductor substrate in at least the semiconductor chip provided between other semiconductor chips,

one of a pair of the first main bump and the first sub-bump of each of the semiconductor chips and a pair of the second main bump and the second sub-bump of each of the semiconductor chips includes a layer to be fluidized by heating as the outermost layer,

a sum of the height of the first main bump from the first surface of each of the semiconductor chips and the height of the second main bump from the second surface of each of the semiconductor chips is smaller than a sum of the height of the first sub-bump from the first surface of each of the semiconductor chips and the height of the second sub-bump from the second surface of each of the semiconductor chips,

at least one of the first main bumps is joined to a second main bump protruded from the second surface of another semiconductor chip at a first joint part by the layer to be fluidized by heating with little collapse, and

at least one of the first sub-bumps is joined to a second sub-bump protruded from the second surface of another semiconductor chip at a second joint part by the layer to be fluidized by heating with large collapse.

In the present invention, sub-bumps greater in height than main bumps are provided, so that the sub-bumps come into contact with one another earlier than the main bumps and serve as stoppers at the time of joining the main bumps. Consequently, it is possible to suppress the thin-filming of a layer between joined main bumps, such as a solder layer, to be fluidized by heating, and therefore, provide a high-reliability semiconductor device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic cross-sectional view of semiconductor device 100 configured by stacking a plurality of semiconductor chips;

FIGS. 2A and 2B are enlarged views, used to describe a method of joining TSVs, wherein FIG. 2A illustrates a state before joint and FIG. 2B illustrates a state after joint;

FIG. 3 is a layout plan view illustrating one example of a semiconductor chip according to one exemplary embodiment of the present invention;

FIGS. 4A and 5A are cross-sectional process drawings, as viewed along the A-A′ line of FIG. 3, used to describe a process of manufacturing a semiconductor chip according to Exemplary Embodiment 1 of the present invention, whereas FIGS. 4B, 5B, 6 to 13, 14A, 14B, 15 to 18, and 20 are cross-sectional process drawings which are used to describe the process of manufacturing the semiconductor chip according to Exemplary Embodiment 1 and correspond to cross-sectional views taken along the B-B′ line of FIG. 3;

FIGS. 19A, 19B and 19C are schematic views illustrating a state of growth of a plated layer in the plating process of FIG. 18;

FIG. 21 is a schematic cross-sectional view illustrating a stacked state of semiconductor chips according to Exemplary Embodiment 1 of the present invention;

FIGS. 22 to 27 are cross-sectional process drawings used to describe a process of manufacturing a semiconductor chip according to Exemplary Embodiment 2 of the present invention, and correspond to cross-sectional views taken along the B-B′ line of FIG. 3;

FIG. 28 is a schematic cross-sectional view illustrating a stacked state of semiconductor chips according to Exemplary Embodiment 2 of the present invention;

FIGS. 29 and 30 are cross-sectional process drawings used to describe a process of manufacturing a semiconductor chip according to Exemplary Embodiment 3 of the present invention, and correspond to cross-sectional views taken along the B-B′ line of FIG. 3;

FIG. 31 is a cross-sectional process drawing used to describe a process of manufacturing a semiconductor chip according to Exemplary Embodiment 4 of the present invention, and corresponds to a cross-sectional view taken along the B-B′ line of FIG. 3;

FIGS. 32A, 33A, 34A, 35A and 36A are cross-sectional process drawings corresponding to the A-A′ cross section of FIG. 3 used to describe a process of manufacturing a semiconductor chip according to Exemplary Embodiment 5 of the present invention, and FIGS. 32B, 33B, 34B, 35B and 36B are cross-sectional process drawings corresponding to the B-B′ cross section of FIG. 3, wherein each drawing illustrates a step prior to substrate backgrinding;

FIGS. 37 to 46 are cross-sectional process drawings corresponding to the B-B′ cross section of FIG. 3, and illustrate a state of a semiconductor device being fixed to WSS 53 and placed upside down; and

FIG. 47 is a schematic view illustrating one example of a data processing system using semiconductor devices of the present invention.

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

In the semiconductor device of the embodiments, a state in which the uppermost layer of interconnects fabricated on a semiconductor substrate and a state in which semiconductor elements are formed on the semiconductor substrate are collectively referred to as a “substrate”. In addition, it is assumed that the semiconductor substrate uses a silicon substrate serving as a base of the substrate. Further, a plurality of semiconductor devices is fabricated on a “wafer” (silicon wafer) and the semiconductor device that is diced from the wafer is referred to as a “semiconductor chip”. The terms “main” and “sub-” are basically used herein to distinguish whether various elements, components, regions, layers etc. are mainly or subsidiary used.

It will be understood that, although the terms first, second, third etc. may be used herein to describe various elements, components, regions, layers etc., these elements, components, regions, layers etc. should not be limited by these terms.

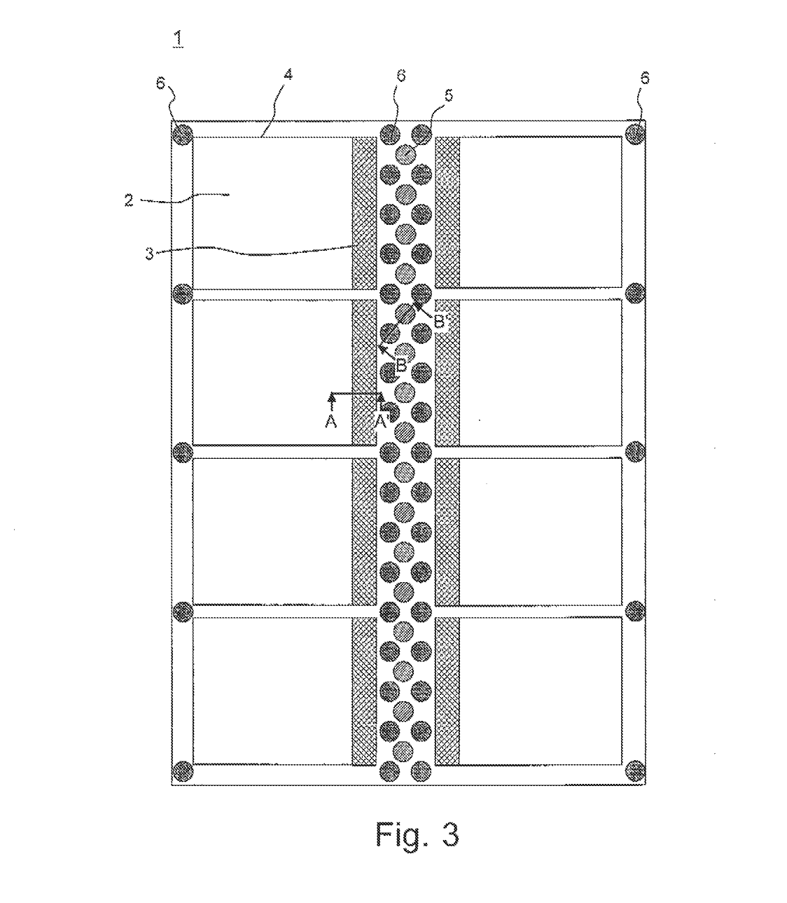

FIG. 3 is a layout plan view illustrating one example of a semiconductor chip according to one exemplary embodiment of the present invention. The figure shows a planar layout on the main surface of semiconductor chip 1 as a core chip which is a DRAM (Dynamic Random Access Memory) provided with memory cell regions 2 including storage elements, and peripheral circuit regions 3 including peripheral circuits formed therein. The planar layout is not limited to this, however. Each memory cell region 2 and each peripheral circuit region 3 constitute each memory mat 4, and main bumps 5 of TSVs are disposed between two rows of memory mats 4. In addition, a plurality of sub-bumps 6 is disposed in proximity to main bumps 5. Sub-bumps 6 are also arranged in the outer circumference of semiconductor chip 1. Note that the layout of main bumps 5 and sub-bumps 6 is one example only and not limited to this layout. Since semiconductor chips are stacked horizontally, at least three sub-bumps 6 may be disposed so as to keep the semiconductor chip in a horizontal position. Preferably, sub-bumps 6 are provided in proximity to main bumps 5.

Main bumps and sub-bumps are also disposed on the rear surface of the semiconductor chip in the same layout as described above, and semiconductor chips sharing the bump layout are joined to each other or one another.

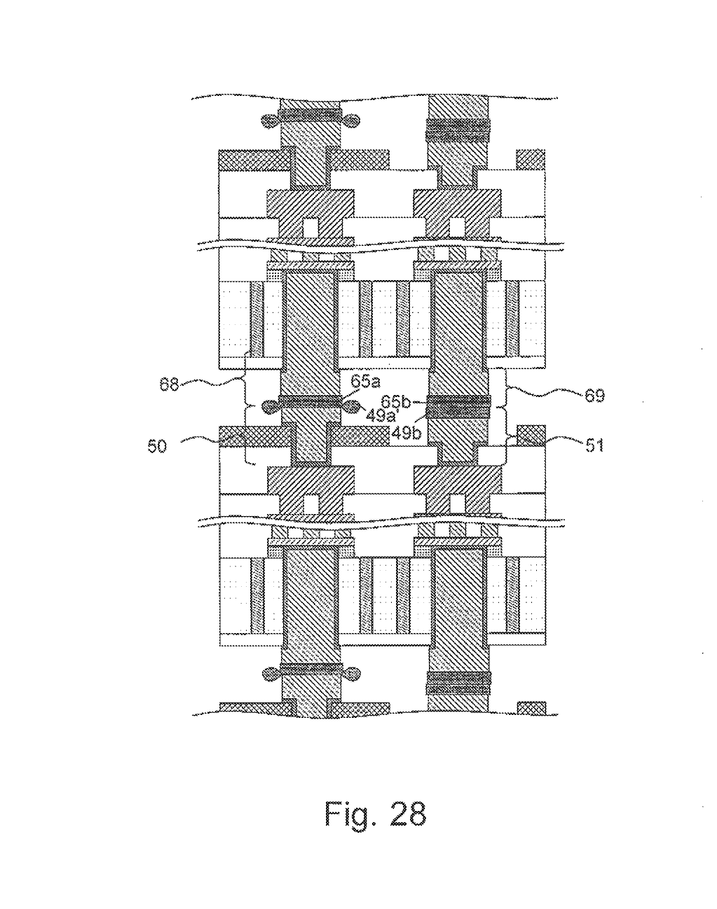

In the present invention, the sub-bumps serve as stoppers at the time of stacking chips, as the result of being formed to be greater in height than the main bumps, and joint margins are secured for the main bumps. Thus, it is possible to suppress the thin-filming of a layer between joined main bumps, such as a solder layer, to be fluidized by heating as illustrated in FIG. 28.

Note that in the present invention, a TSV provided with main bumps is referred to as a main TSV for the reason that the TSV is used mainly as a current pathway, and a TSV provided with sub-bumps is referred to as a sub-TSV. The sub-TSV is a dummy which is normally not used as a current pathway, but can be used as a subsidiary current pathway, such as a current pathway for releasing static electricity or the like.

### EXEMPLARY EMBODIMENTS

Hereinafter, specific examples of manufacturing a semiconductor device of the present invention will be shown by citing exemplary embodiments, though the present invention is not limited to these exemplary embodiments only.

### Exemplary Embodiment 1

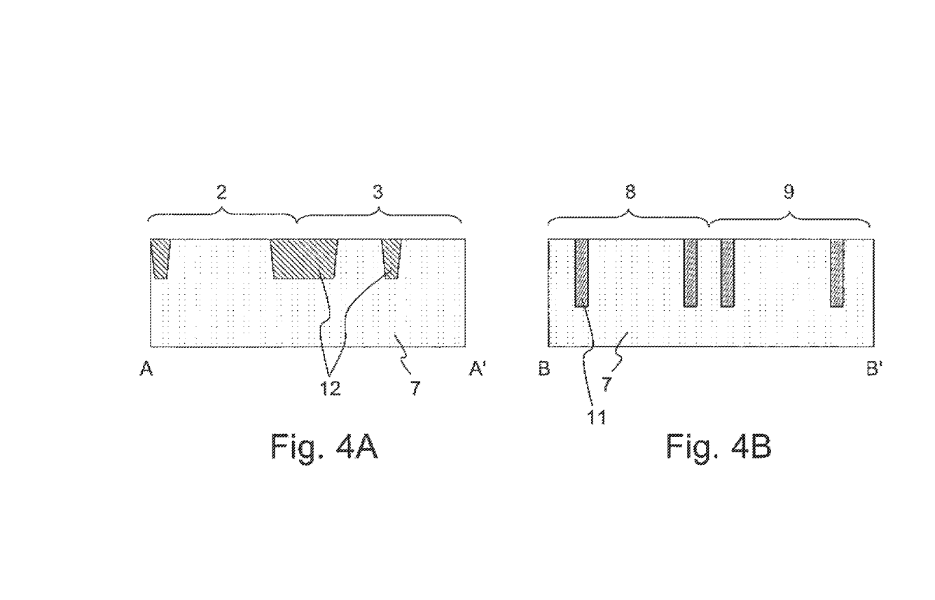

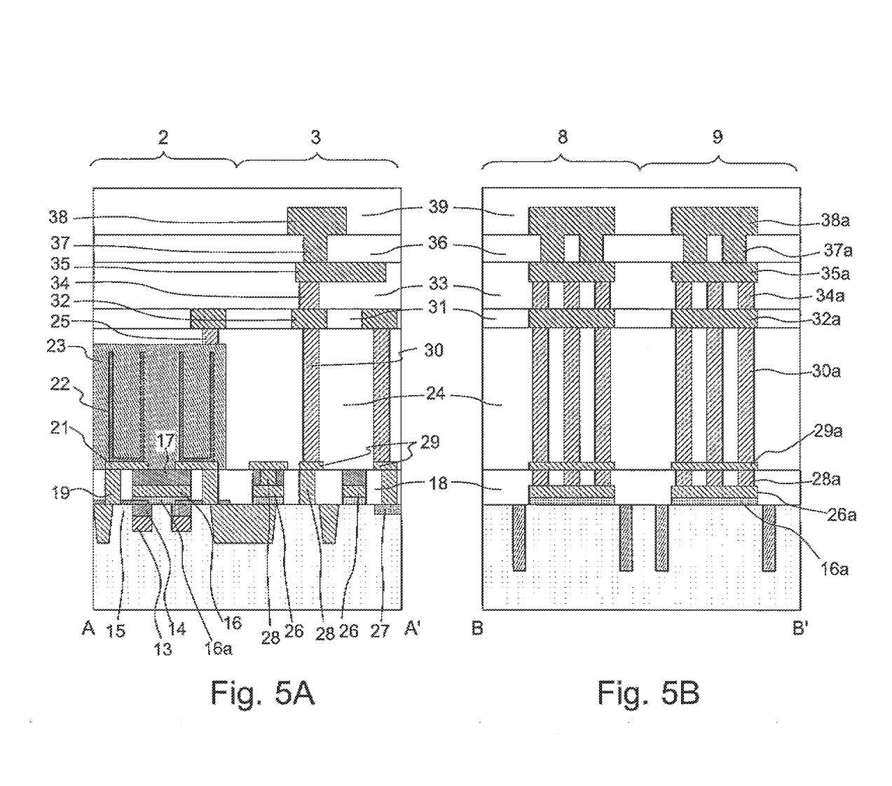

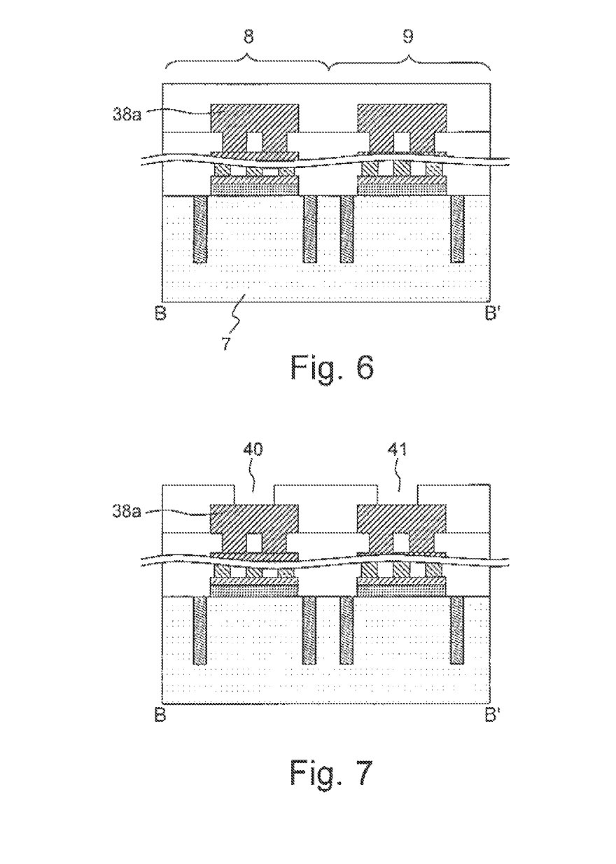

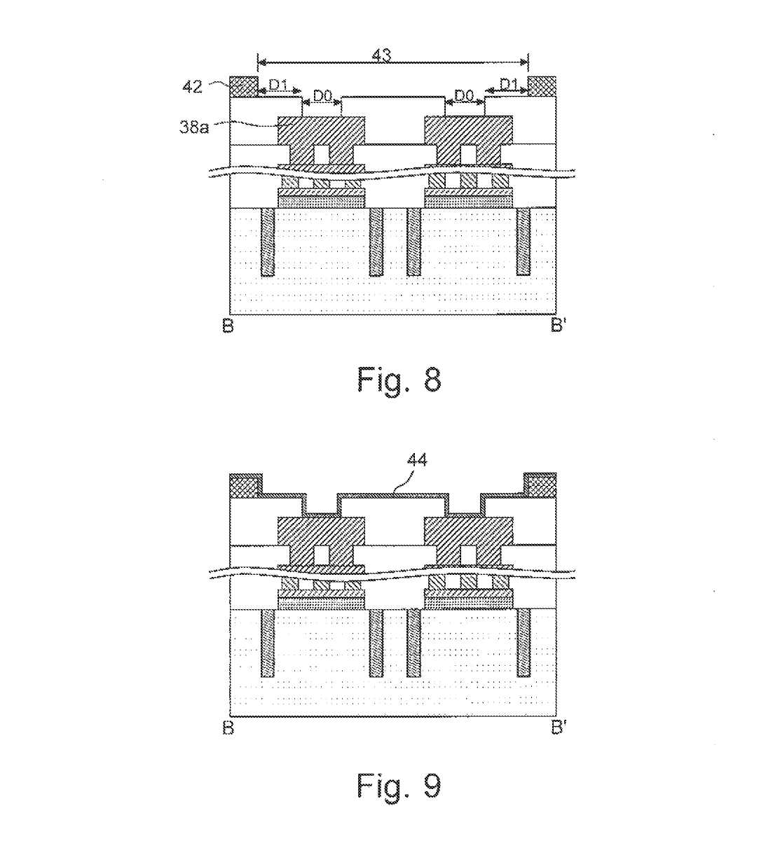

FIGS. 4A and 5A are cross-sectional process drawings, as viewed along the A-A′ line of FIG. 3, used to describe a process of manufacturing a semiconductor chip according to Exemplary Embodiment 1 of the present invention, whereas FIGS. 4B, 5B, 6 to 13, 14A, 14B, 15 to 18, and 20 are cross-sectional process drawings which are used to describe the process of manufacturing the semiconductor chip according to Exemplary Embodiment 1 and correspond to cross-sectional views taken along the B-B′ line of FIG. 3. Note that a scale in each figure is optional and differs from the scale of an actual device configuration.

First, as illustrated in FIG. 4A, STIs 12 for element isolation are formed in memory cell region 2 and peripheral circuit region 3 of semiconductor substrate 7. On the other hand, as illustrated in FIG. 4B, annular insulating region 11 for ensuring insulation from a semiconductor element and the like, which are formed in memory cell region 2 and peripheral circuit region 3, is formed in a TSV-forming region. In general, annular insulating region 11 is formed to a width of approximately 2 to 3 μm and a depth of approximately 50 μm. In contrast, each STI is formed to a depth of approximately several hundred nm. In FIG. 4B, reference numeral 8 denotes a region in which a sub-TSV is to be formed (hereinafter abbreviated as sub-TSV-forming region), and reference numeral 9 denotes a region in which a main TSV is to be formed (hereinafter abbreviated as main TSV-forming region).

Next, on the main surface of the semiconductor substrate, semiconductor circuits such as a semiconductor element and an interconnect layer are formed in memory cell region 2 and peripheral circuit region 3, and members, such as pads and via plugs, which constitute part of a TSV of the same layer are formed in sub-TSV-forming region 8 and main TSV-forming region 9. For example, as illustrated in FIG. 5A, buried word lines 13 (insulated from semiconductor substrate 7 by an unillustrated gate insulating film) to serve as gate electrodes of transistors, and buried-gate cell transistors provided with cap insulating layer 14 and diffusion layer 15 are formed in memory cell region 2. Two cell transistors share one diffusion layer 15, and bit line 16 is connected to shared diffusion layer 15 through silicon film 16a serving as a bit line contact. Cover film 17 for covering bit line 16 is provided thereon. In addition, storage-node contact plug 19 is connected to each unshared diffusion layer 15. First interconnects 26 formed in the same layer as silicon film 16a and bit line 16, diffusion layer 27 of a transistor (not illustrated) in peripheral circuit region 3, contact plug 28, and the like are provided in peripheral circuit region 3. Silicon film 16a, first interconnect pad 26a, and first via plug 28a are also provided in the same layer in sub-TSV-forming region 8 and main TSV-forming region 9. These structures on semiconductor substrate 7 are formed within first interlayer insulating film 18.

Storage-node pad 21, capacitor 22, storage-node plate 23, and first via plug 25 are provided in memory cell region 2 in a layer of second interlayer insulating film 24. Second interconnects 29 and second via plugs 30 are provided in peripheral circuit region 3. Second interconnect pads 29a and second via plugs 30a are also provided in the same layer of sub-TSV-forming region 8 and main TSV-forming region 9.

In addition, third interconnect 32 and third interconnect pad 32a are provided in third interlayer insulating film 31, third via plug 34, 34a, fourth interconnect 35, and fourth interconnect pad 35a are provided in fourth interlayer insulating film 33, fourth via plug 37, 37a is provided in fifth interlayer insulating film 36, and fifth interconnect 38 and fifth interconnect pad 38a are provided on fifth interlayer insulating film 36, respectively, in an upper layer. Yet additionally, protective film 39 is provided on the uppermost layer.

Each interlayer insulating film is composed of a silicon oxide film, cover film 17 and protective film 39 are composed of a silicon nitride film, and each interconnect and each via plug are composed of a conductive material such as metal.

Next, a method of forming TSVs will be described with reference to the B-B′ cross section of FIG. 3. FIGS. 6 to 18 and 20 are schematic views from which the second to fifth interlayer insulating films are omitted. FIG. 6 corresponds to FIG. 5B.

First, as illustrated in FIG. 7, first sub-bump hole 40 and first main bump hole 41 to expose therein surfaces of fifth interconnect pads 38a are formed in protective film 39.

Subsequently, as illustrated in FIG. 8, a 5 μm-thick polyimide film (PIQ) to be used as a protective film (passivation film) is coated on the entire surface of the device being fabricated. Then, PIQ hole 43 to serially expose therein first sub-bump hole 40 and first main bump hole 41 is formed by lithography and oxygen dry etching. Diameters D0 of both first sub-bump hole 40 and first main bump hole 41 are set to 15 μm. In addition, distances D1 from the side walls of PIQ hole 43 to the side walls of both first sub-bump hole 40 and first main bump hole 41 are set to 30 μm.

Next, as illustrated in FIG. 9, a 150 nm-thick titanium film and a 300 nm-thick Cu film are laminate-formed by a sputtering method on the entire surface of the device being fabricated to form first feed layer 44.

As illustrated in FIG. 10, a 20 μm-thick photoresist 45 is formed on the entire surface of the device being fabricated, and first sub-bump opening 46 and first main bump opening 47 are formed by lithography. Aperture diameters D3 of first sub-bump opening 46 and first main bump opening 47 are set to 25 μm. At this time, distance D2 between side wall 46a of first sub-bump opening 46 and first sub-bump hole 40 is 5 μm, and distance D2 between side wall 47a of first main bump opening 47 and first main bump hole 41 is also set to 5 μm.

As illustrated in FIG. 11, the substrate is immersed in a Cu plating liquid from the side of the first sub-bump opening 46 and first main bump opening 47. Then, 11 μm-thick first Cu sub-layer 48a and first Cu main layer 48b are formed in first sub-bump opening 46 and first main bump opening 47, respectively, by electrolytic plating, while feeding power to first feed layer 44, thereby serially growing first metal joining sub-layer 49a and first metal joining main layer 49b made of a 3 μm-thick Sn—Ag alloy. At this time, first metal joining sub-layer 49a and first metal joining main layer 49b are formed so that surfaces thereof are not higher than the upper surface of photoresist 45.

As illustrated in FIG. 12, exposed portions of first feed layer 44 are removed after photoresist 45 is removed, thereby forming first sub-bump 50 and first main bump 51 that are formed over the substrate to protrude from a first surface of the substrate.

Then, 50 μm-thick adhesive layer 52 is formed on the entire surface of the device being fabricated. Wafer support system (WSS) 53 made of a 675 μm-thick glass substrate almost the same in diameter as the semiconductor substrate (silicon wafer) is bonded onto adhesive layer 52 (FIG. 13).

The substrate (wafer) is held on WSS 53 to grind the rear surface of the semiconductor substrate. Hereafter, each drawing is shown upside down. FIG. 14A illustrates a state prior to backgrinding, and thickness H1 of semiconductor substrate 7 is, for example, 775 μm. This semiconductor substrate is ground until the bottom of insulating region 11 becomes exposed, i.e., thickness H2 after grinding reaches 50 μm, as illustrated in FIG. 14B. Thereafter, the rear surface of semiconductor substrate 7 is polished by a chemical-mechanical polishing (CMP) method.

Rear-surface protective film 54 made of 300 nm-thick silicon nitride is formed across the polished rear surface by a plasma CVD method. Subsequently, 50 μm-thick photoresist 55 is coated on the entire rear surface, and second sub-bump hole pattern 56 and second main bump hole pattern 57 are formed by photolithography. These hole patterns are formed so that diameter D4 of second sub-bump hole pattern 56 is smaller than diameter D5 of second main bump hole pattern 57. For example, the hole patterns are formed so that D4 is 10 μm and D5 is 15 μm. A pattern on a mask used in the lithography of photoresist 55 is previously formed in conformity to those dimensions, and the hole patterns are formed by one-shot exposure (FIG. 15).

Using photoresist 55 as the mask, rear-surface protective film 54, semiconductor substrate 7 and silicon film 16a are dry-etched to form second sub-bump hole 58 and second main bump hole 59 to expose therein first interconnect pad 26a (FIG. 16).

Next, a 250 nm-thick titanium film and a 750 nm-thick Cu film are sequentially formed on the entire rear surface by a sputtering method to form second feed layer 60. Thereafter, 12 μm-thick photoresist 61 is formed on the entire rear surface to form second sub-bump opening 62 and second main bump opening 63 by photolithography. Second sub-bump opening 62 and second main bump opening 63 have the same diameter denoted by D6 which is set to 22 μm. Side surface 62a formed by coating a side wall of second sub-bump hole 58 with second feed layer 60 and upper surface 62b formed by coating second feed layer 60 on rear-surface protective film 54 are exposed in second sub-bump opening 62. On the other hand, side surface 63a formed by coating a side wall of second main bump hole 59 with second feed layer 60 and upper surface 63b formed by coating second feed layer 60 on rear-surface protective film 54 are exposed in second main bump opening 63. Diameter D4a of side surface 62a equals a value given by subtracting a value (2 μm) twice the 1 μm film thickness of second feed layer 60 from D4, i.e., 8 μm. Diameter D5a of side surface 63a is likewise calculated to be 13 μm (FIG. 17).

As illustrated in FIG. 18, the substrate is immersed in a Cu plating liquid from the side of the second sub-bump opening 62 and second main bump opening 63. Then, second Cu sub-layer 64a and second Cu main layer 64b are formed in second sub-bump opening 62 and second main bump opening 63, respectively, by electrolytic plating, while feeding power to second feed layer 60, thereby sequentially forming a 3 μm-thick Ni plated layer and a 0.1 μm-thick Au plated layer to be grown second metal joining sub-layer 65a and second metal joining main layer 65b. Here, second Cu sub-layer 64a is formed to be greater in height than second Cu main layer 64b since the sidewalls are formed so that diameter D4a of sidewall 62a is smaller than diameter D5a of sidewall 63a.

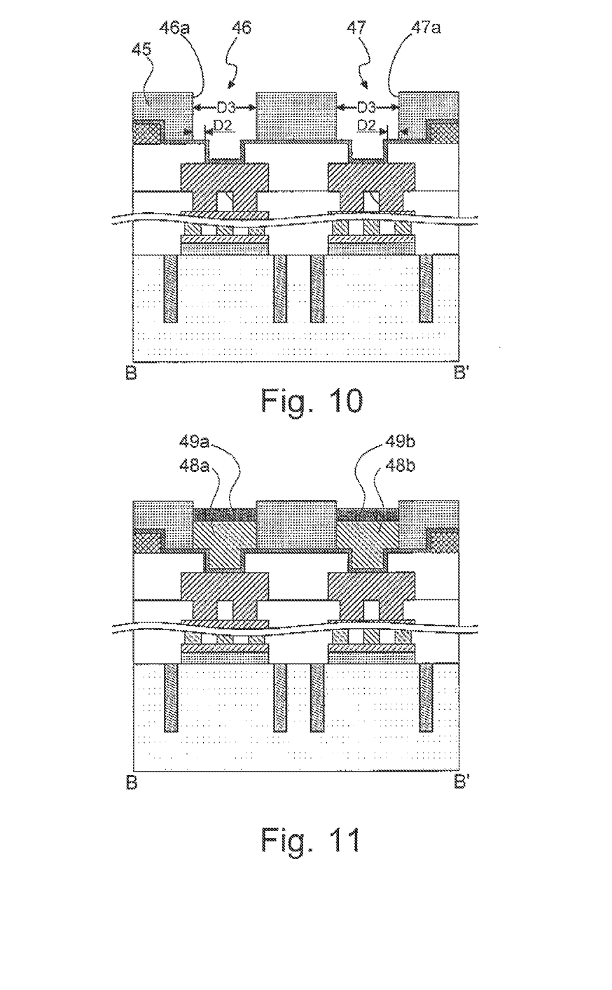

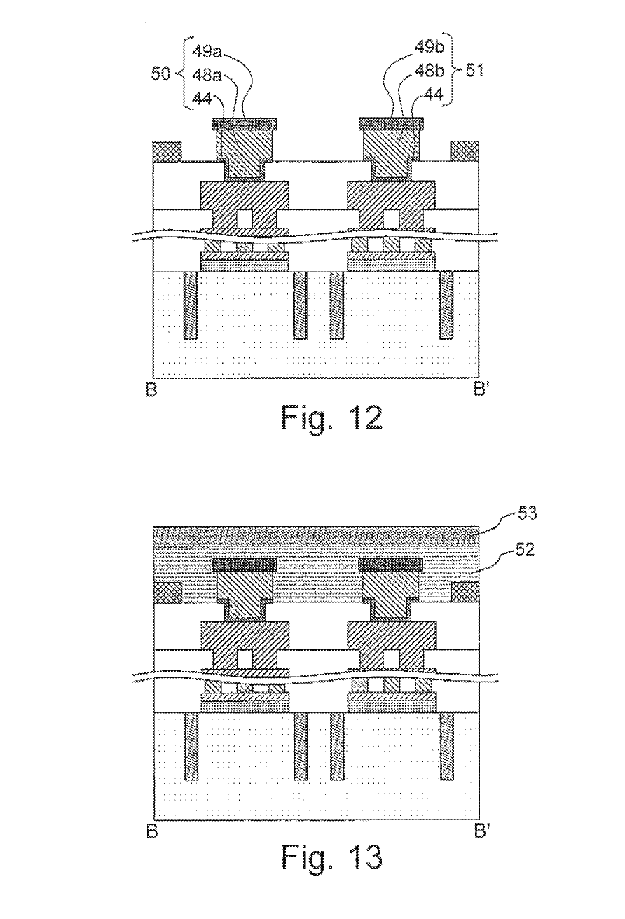

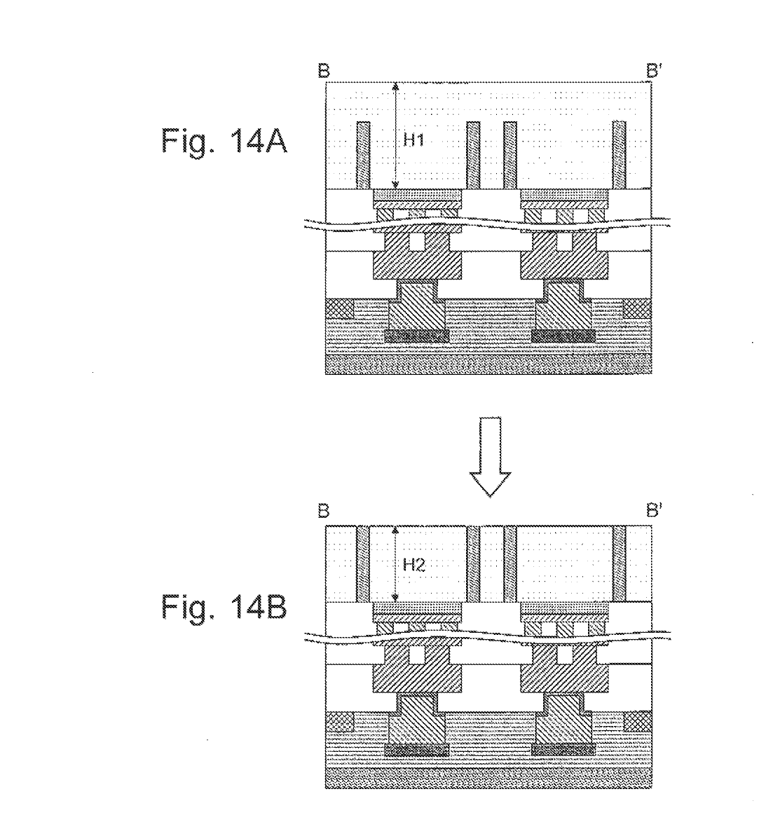

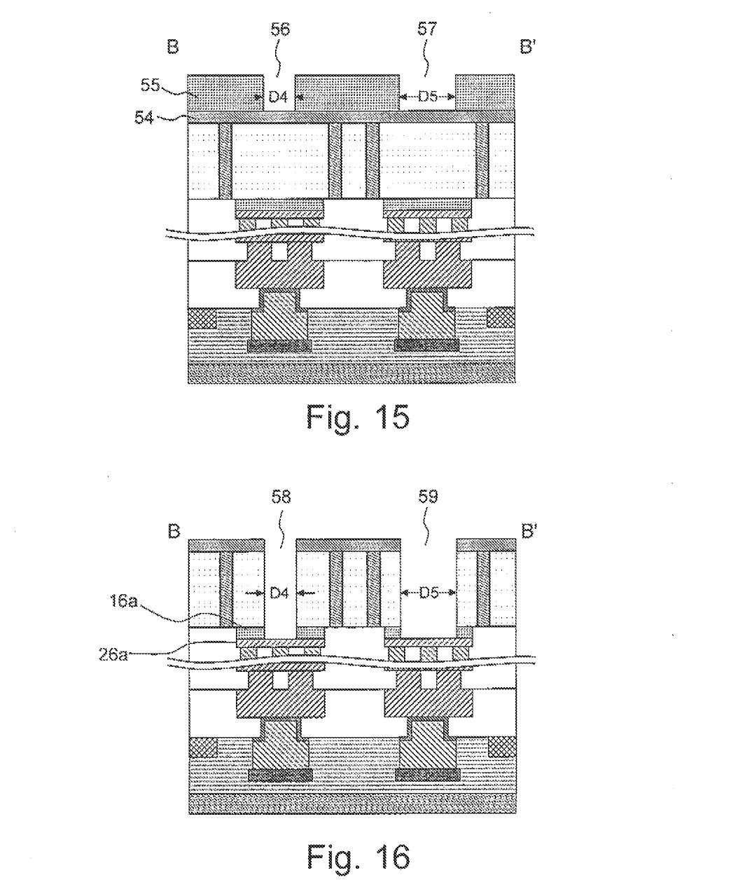

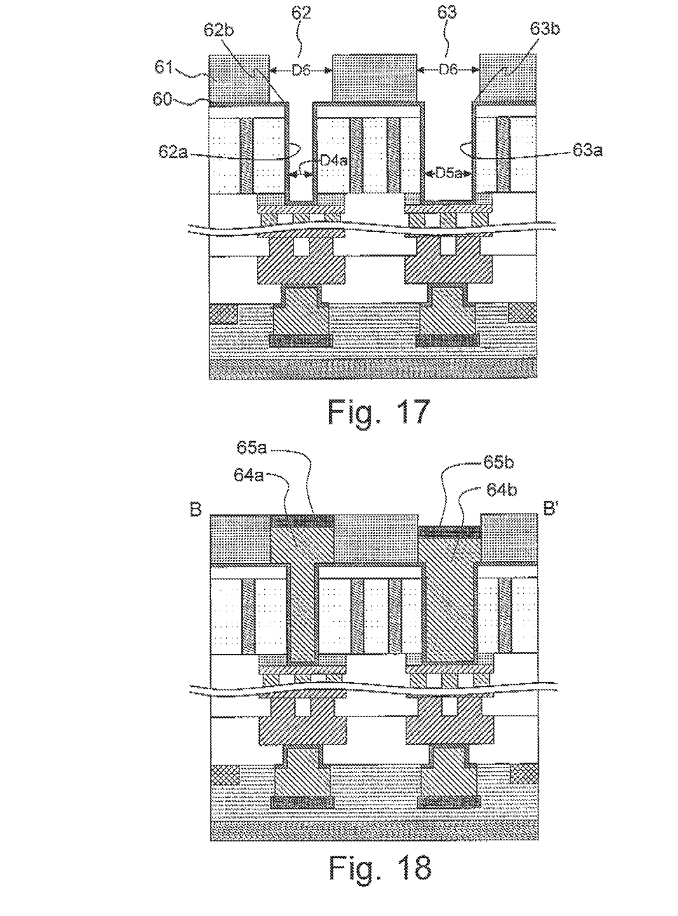

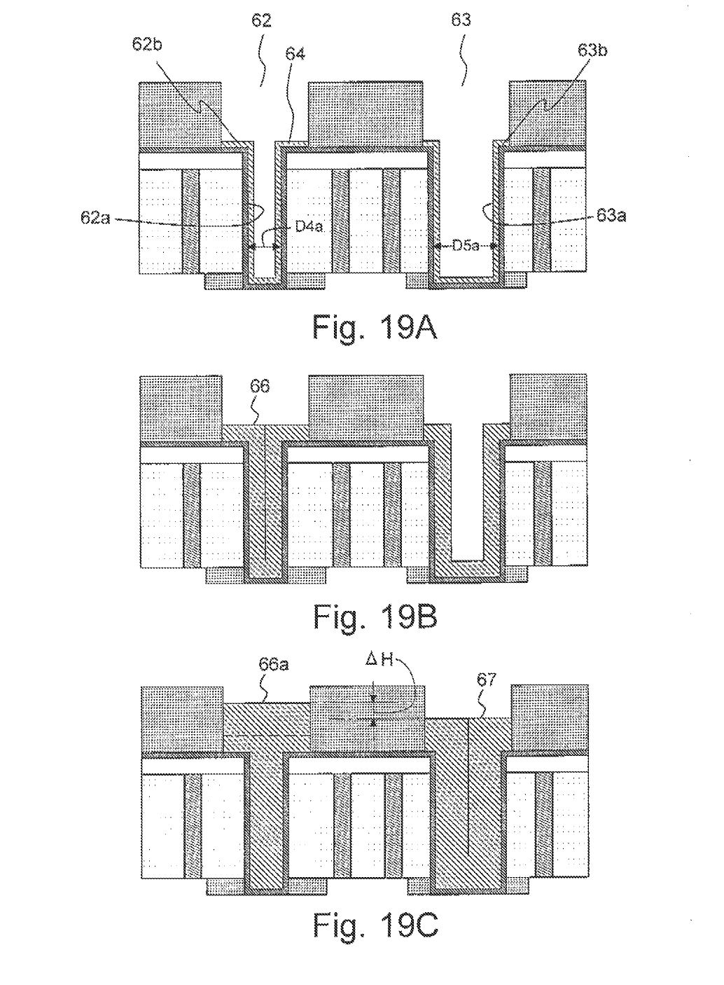

FIGS. 19A to 19C are conceptual views illustrating, by way of example, a process of forming second Cu sub-layer 64a and second Cu main layer 64b. FIG. 19A illustrates a state at an initiation step in which the growth of Cu film 64 is initiated from side surfaces 62a and 63a and upper surfaces 62b and 63b on which second feed layer 60 is exposed, with second feed layer 60 as a core. When the thickness of Cu film 64 reaches half the diameter D4a between side surfaces 62a, i.e., 4 μm, Cu films 64 come into contact with each other within second sub-bump opening 62 to form first upper surface 66, as illustrated in FIG. 19B. On the other hand, Cu films 64 are not in contact with each other within second main bump opening 63. When the growth of Cu film 64 is continued further and the thickness of Cu film 64 reaches half diameter D5a between side surfaces 83a, i.e., 6.5 μm, Cu films 64 come into contact with each other also within second main bump opening 63 to form second upper surface 67. At this time, first upper surface 66 serves as a growth face within second sub-bump opening 62, and the growth face is smaller in area than a growth face within the second main bump opening 63. As a result, at the stage of second upper surface 67 being formed, the first upper surface (66a) is at a height of 9 μm from upper surface 62b. Consequently, difference ΔH in height of the first upper surface 66a from second upper surface 67 is 2.5 μm. In this way, Cu layer 64a of the second sub-bump can be made greater in height than Cu layer 64b of second main bump by forming the bump holes, so that diameter D4 of second sub-bump hole 58 is smaller than diameter D5 of second main bump hole 59 (FIG. 19C). Thereafter, second metal joining sub-layer 65a and second metal joining main layer 65b are formed on first upper surface 66a and second upper surface 67 having the same growth area and are, therefore, formed to the same thickness.

Thereafter, photoresist 61 and exposed portions of second feed layer 60 are removed, thereby forming second sub-bump 68 and second main bump 69 formed over substrate 70 to protrude from the second surface of substrate 70, as illustrated in FIG. 20. Second sub-bump 68 is greater in height than second main bump 69, whereas first sub-bump 50 and first main bump 51 are level with each other.

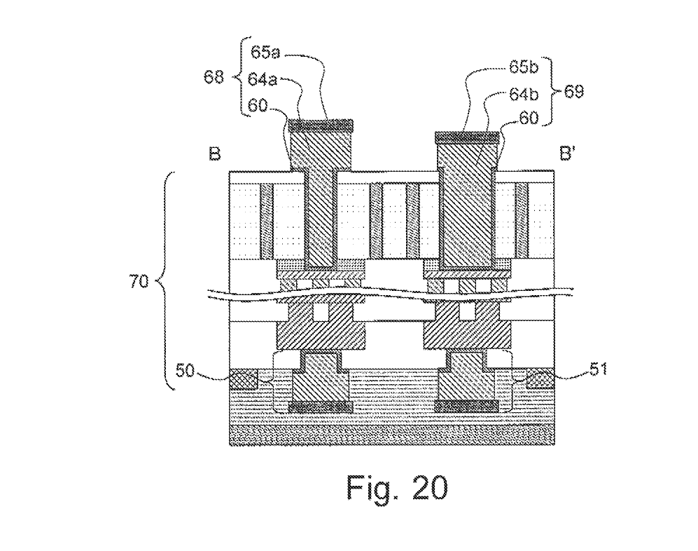

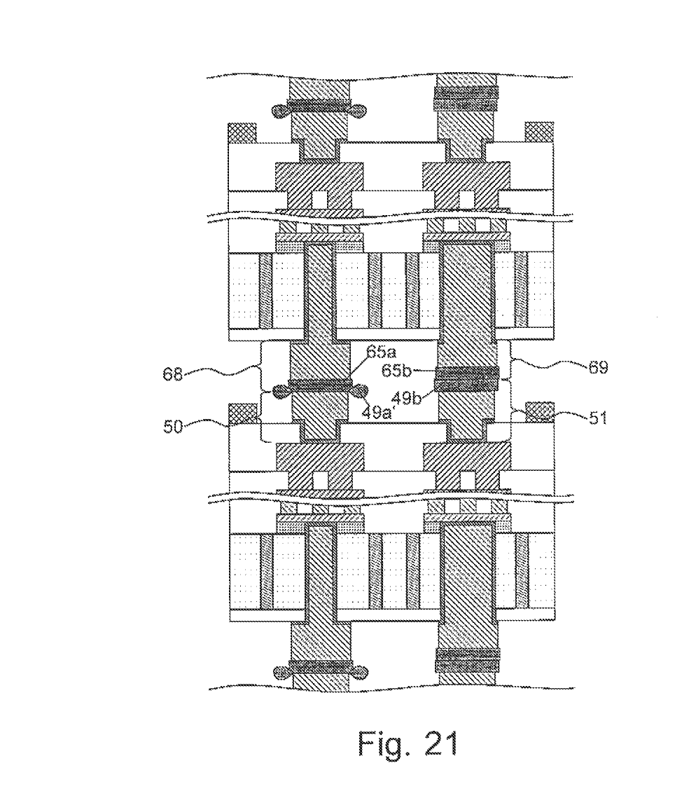

FIG. 21 illustrates a state in which a plurality of semiconductor chips provided with TSVs and manufactured as described above is stacked. In the present exemplary embodiment, the first metal joining layer constituting first sub-bump 50 and first main bump 51 is formed of a Sn—Ag alloy, and the second metal joining layer constituting second sub-bump 68 and second main bump 69 is formed of an Au/Ni laminated film. The thicknesses of both the first metal joining layer and the second metal joining layer are set to 3 μm, and second sub-bump 68 is formed so as to protrude 2.5 μm above second main bump 69. At this time, at a joint between the first and the second sub-bumps, second metal joining sub-layer 65a remains substantially intact during heating as the layer is high in the degree of hardness, whereas first metal joining sub-layer 49a is fluidized by heating and therefore collapses and extrudes out the periphery, thus forming side drop 49a′ as in the conventional semiconductor device. On the other hand, first metal joining main layer 49b collapses only slightly at a joint between the first and second main bumps, since a 2.5 μm margin of height is present in the joint. Thus, the first and second main bumps can be joined without allowing any side drops to be formed therebetween. This eliminates the possibility that joint strength decreases at bumps serving as current pathways to induce bump cracks. In addition, the amount of segregated Au is small even if thermal stress caused by a reliability test or the like is applied. This suppresses the phenomenon that cracks occur or interfacial resistance increases. Yet additionally, the thin-filming of a solder layer can be suppressed even if a preliminary solder reflow process cannot be fully carried out for reasons of process steps.

The present exemplary embodiment uses a method in which variations are previously made to the diameters of a plurality of holes in which TSVs are to be formed. Then, the method takes advantage of the fact that an area of Cu film growth reduces in a self-aligned manner in a narrow hole to increase the growth rate of a Cu film in the height direction thereof. Consequently, an upper surface of the Cu film formed in the narrow hole is relatively greater in height at the moment that the burial of the Cu film in a wide hole is completed. With this method, the upper surface of a sub-bump is made greater in height than the upper surface of a main bump, thereby suppressing thin-filming due to the collapse of a solder layer in the main bump.

### Exemplary Embodiment 2

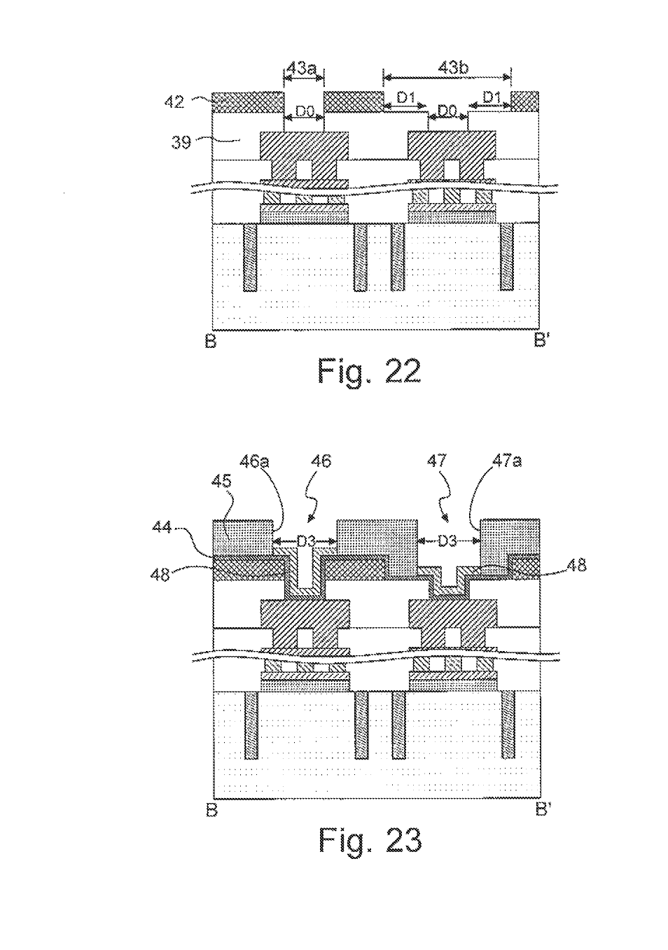

In the formation of a front bump in Exemplary Embodiment 1, offsets D1 of 30 μm are secured for both first sub-bump hole 40 and first main bump hole 41 to form PIQ hole pattern 43, so that the first sub-bump and the first main bump are the same in shape. In the present exemplary embodiment, however, PIQ hole pattern 43a surrounding first sub-bump hole 40 is formed so that the diameter of the hole pattern is the same as or larger, within the upper limit of approximately 2 μm, than diameter D0 of first sub-bump hole 40. On the other hand, PIQ hole pattern 43b surrounding first main bump hole 41 is formed while securing offset D1 of 30 μm as in Exemplary Embodiment 1 (FIG. 22).

Next, photoresist 45 is formed after first feed layer 44 is formed in the same way as in Exemplary Embodiment 1. Then, first sub-bump opening pattern 46 and first main bump opening pattern 47 having diameter D3 are likewise formed. Thereafter, Cu film 48 is grown by a plating method (FIG. 23).

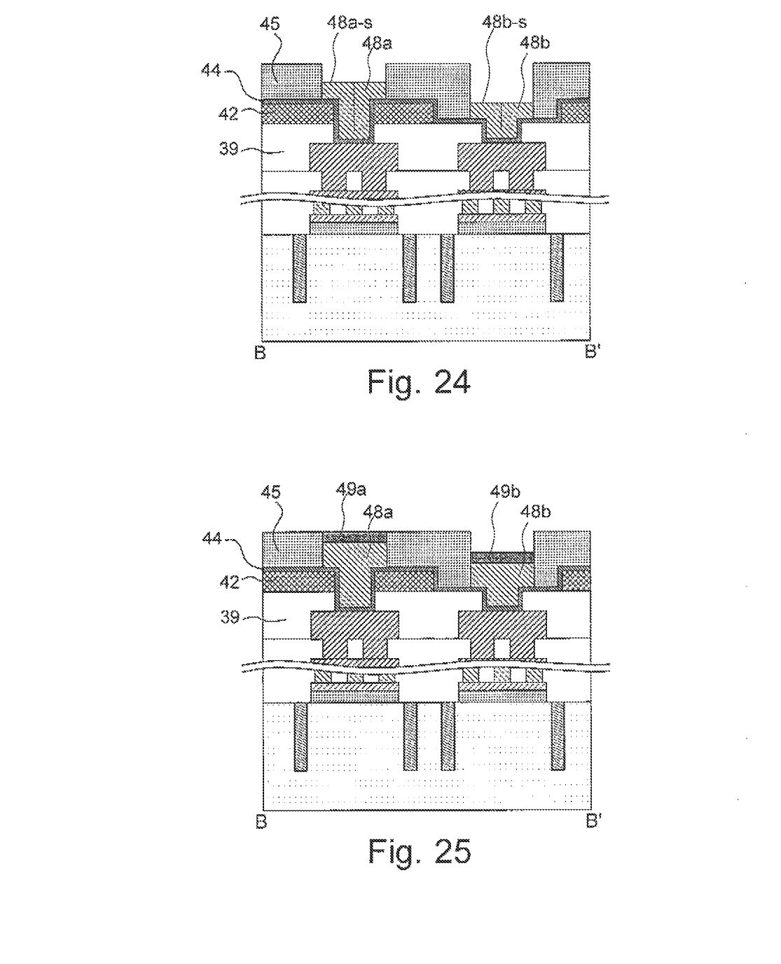

Since first sub-bump opening pattern 46 and first main bump opening pattern 47 have the same diameter D3, burial is completed at the same point in time in both holes. That is, the growth heights of the outer edges of first sub-bump hole 40 and first main bump hole 41 from the upper surface of first feed layer 44 are the same. Accordingly, first Cu sub-layer 48a having surface 48a-s is formed in first sub-bump opening pattern 46 and first Cu main layer 48b having surface 48b-s is formed in first main bump opening pattern 47. At this time, since the first Cu sub-layer is elevated by as much as the height of PIQ layer 42 in first sub-bump hole 40, surface 48a-s of first Cu sub-layer 48a is greater in height than surface 48b-s of first Cu main layer 48b (FIG. 24).

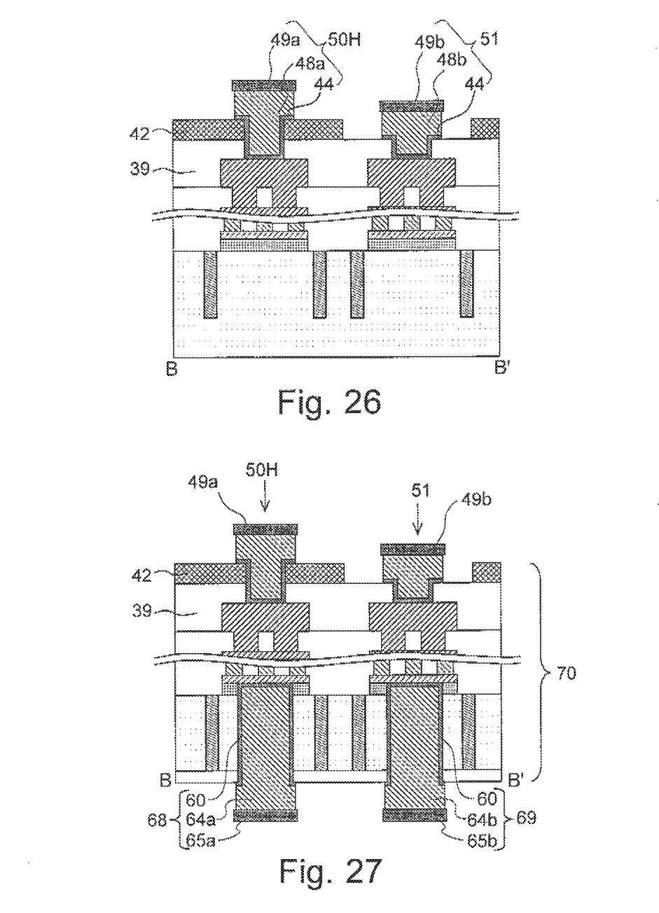

Thereafter, first metal joining sub-layer 49a and first metal joining main layer 49b made of a 3 μm-thick Sn—Ag alloy are formed in the same way as in Exemplary Embodiment 1 (FIG. 25). Subsequently, exposed potions of first feed layer 44 are removed after photoresist 45 is removed, thereby forming first sub-bump 50H greater in height than first main bump 51, as illustrated in FIG. 26.

Hereafter, backgrinding is performed in the same way as in Exemplary Embodiment 1 to form second sub-bump 68 and second main bump 69. Unlike Exemplary Embodiment 1, second sub-bump 68 and second main bump 69 are formed over substrate 70 to protrude from the second surface of substrate 70 so as to be the same in shape (FIG. 27).

If a plurality of semiconductor chips including TSVs thus formed is stacked, first metal joining sub-layer 49a collapses and extrudes out the periphery to form side drop 49a′ at a part (a second joint part) where elevated first sub-bump 50H and second sub-bump 68 are in contact with each other, as in Exemplary Embodiment 1. First metal joining main layer 49b collapses only slightly, however, at a part (a first joint part) where first main bump 51 and second main bump 69 are contact with each other, and does not form any side drops (FIG. 28).

### Exemplary Embodiment 3

In the steps of FIGS. 15 and 16 in Exemplary Embodiment 1, second sub-bump hole 58 is formed so as to be smaller in diameter (D4) than second main bump hole 59, in the present exemplary embodiment, however, an example is shown in which after second sub-bump hole 58 is formed so as to be the same in diameter (D5) as second main bump hole 59, the diameters of openings formed in a photoresist to serve as a plating mask are varied to make a height variation between second sub-bump hole 58 and second main bump hole 59.

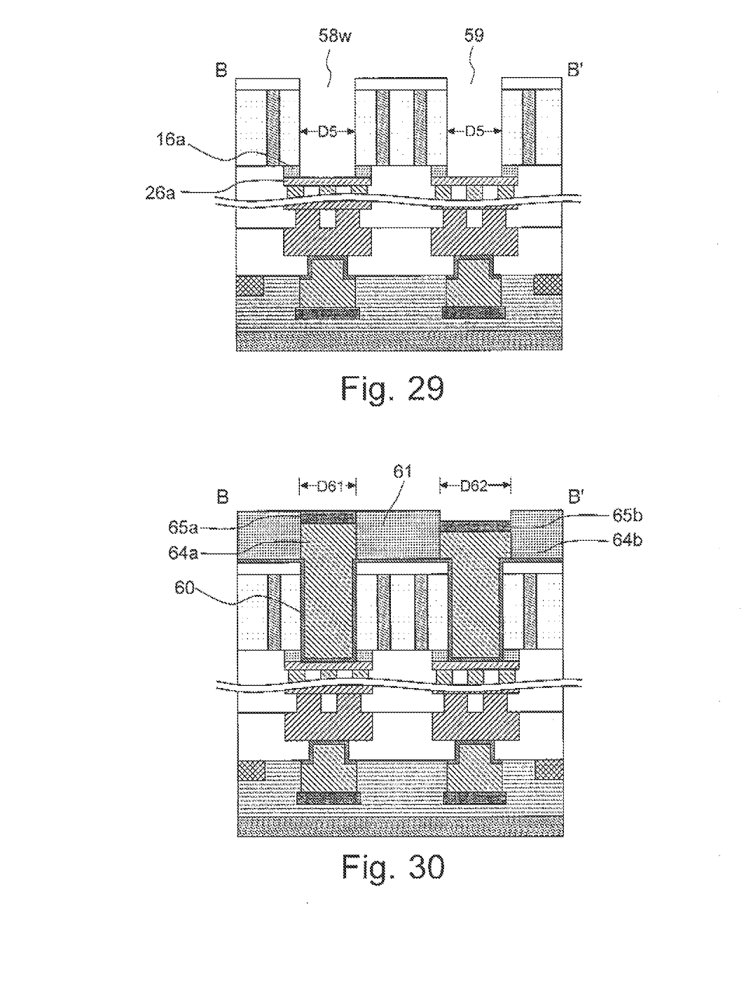

First, rear-surface protective film 54 is formed after carrying out steps up to the step of FIG. 14 in the same way as in Exemplary Embodiment 1. Then, second sub-bump hole pattern 56 and second main bump hole pattern 57 are formed in photoresist 55, so as to have diameter D5, and etching is performed in the same way as in Exemplary Embodiment 1. This process forms second sub-bump hole 58w and second main bump hole 59 having diameter D5, as illustrated in FIG. 29.

Next, after second feed layer 60 is formed, second sub-bump opening 62 is formed in photoresist 61, so as to have diameter D61, and second main bump opening 63 is formed so as to have diameter D62. If electrolytic Cu film plating is performed under this condition, the plugging of the second sub-bump hole and second main bump hole occurs at the same point in time. Subsequent growth progresses faster in second sub-bump opening 62 smaller in diameter, however. Consequently, second Cu sub-layer 64a becomes greater in surface height than second Cu main layer 64b. In addition, second metal joining sub-layer 65a formed in second sub-bump opening 62 smaller in diameter becomes greater in thickness than second metal joining main layer 65b formed in second main bump opening 63. Accordingly, second sub-bump can be made greater in height than second main bump (FIG. 30).

### Exemplary Embodiment 4

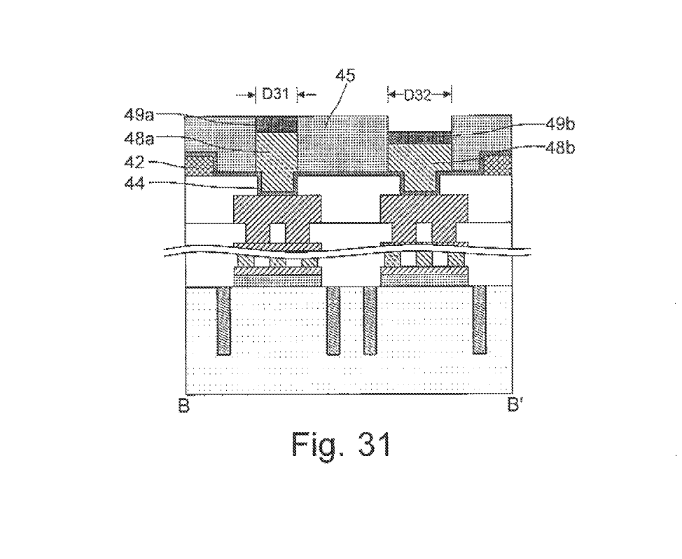

In Exemplary Embodiment 3, a case has been shown in which variations are made to the diameters of bump openings formed in a photoresist to serve as a plating mask at the time of forming a rear bump. This method can also be applied to a front bump, FIG. 31 illustrates a state of a first sub-bump being made greater in height than a first main bump by forming front bumps, so that first sub-bump aperture diameter D31 and first main bump aperture diameter D32 satisfy the relationship D31<D32.

Note that in the above-described exemplary embodiments, cases have been described in which either one of front and rear sub-bumps is made greater in height. It is also possible, however, to increase the heights of both sub-bumps. For example, if a height difference of one sub-bump is not adequate as a joint margin, the bump heights may be changed on both the front and rear surfaces. Thus, sufficient joint margins can be secured. That is, TSVs are formed so that the length of a sub-TSV in the substrate thickness direction is greater than the length of a main TSV in the substrate thickness direction with a predetermined joint margin secured therebetween, in either case, adjustments are made so as to be able to secure desired joint margins.

Joint margins to be secured may be selected as appropriate, according to the thicknesses and materials of the first and second metal joining layers, so as to be optimum. A joint margin of 1 μm or larger is preferred since it is possible to suppress a decrease in joint strength due to the segregation of Au. An upper limit of joint margins should be within the range in which main bumps are securely joined to each other. That is, the upper limit should be no greater than the film thickness of a solder layer included in either the first metal joining layer or the second metal joining layer of a main TSV.

In the present invention, a height variation is made between a sub-bump and a main bump to avoid the collapse of a joining layer. Thus, the present invention also has the advantageous effect that constrains on the materials of metal joining layers are relaxed. As a result, the materials are not limited to those shown in the exemplary embodiments, including a Sn—Ag alloy used as the first metal joining layer and a Ni/Au laminated film used as the second metal joining layer, but a combination of various materials is applicable. That is, in the present invention, one of a pair of the first main bump and the first sub-bump and a pair of the second main bump and the second sub-bump includes a layer to be fluidized by heating as the outermost layer. Examples of the combination include:

(1) front bump: Au/Ni/Cu, rear bump: Sn—Ag/Ni/Cu;

(2) front bump: Sn—Ag/Ni/Cu, rear bump: Au/Ni/Cu;

(3) front bump: Au/Ni/Cu, rear bump: Sn—Ag/Cu; and

(4) front bump: Sn—Ag/Cu, rear bump: Au/Ni/Cu.

Also in the present invention, an example has been cited in which a sub-bump is formed as part of a sub-TSV, in order to ensure that the mechanical strength of the sub-TSV at the time of joining is substantially the same as that of a main TSV. If the electrodes have no problems in terms of mechanical strength, first and second sub-bumps may be formed on both surfaces of a substrate without being electrically connected to each other. For example, in FIG. 5B, first via plug 28a to fourth via plug 37a may be omitted in sub-TSV-forming region 8.

In addition, in the description given above, a case has been shown in which annular insulating region 11 is formed. Insulation is not limited to this method, however. Alternatively, an insulating layer may be formed on sidewalls of a plug penetrating through the semiconductor substrate to insulate the semiconductor substrate and the plug from each other. In a case where annular insulating region 11 is formed, the insulating region is not limited to such a single-ringed annular structure as illustrated in the figure, but may be a double or more-ringed annular structure.

Yet additionally, in the description given above, a case has been shown in which the second man bump and the second main bump and the second sub-bump are formed integrally with plugs penetrating through the semiconductor substrate. Bump formation is not limited to this method, however. Alternatively, the second main bump and the second sub-bump may be formed separately. If the bumps are formed separately and the second sub-bump is made greater in height than the second main bump, it is possible to apply such a technique of varying the aperture diameter of a plating mask as shown in Exemplary Embodiment 3. If the bumps are formed separately in this way, only the bump structures of the rear surface of the semiconductor substrate may be formed without providing a plug penetrating through the semiconductor substrate for the second sub-bump.

### Exemplary Embodiment 5

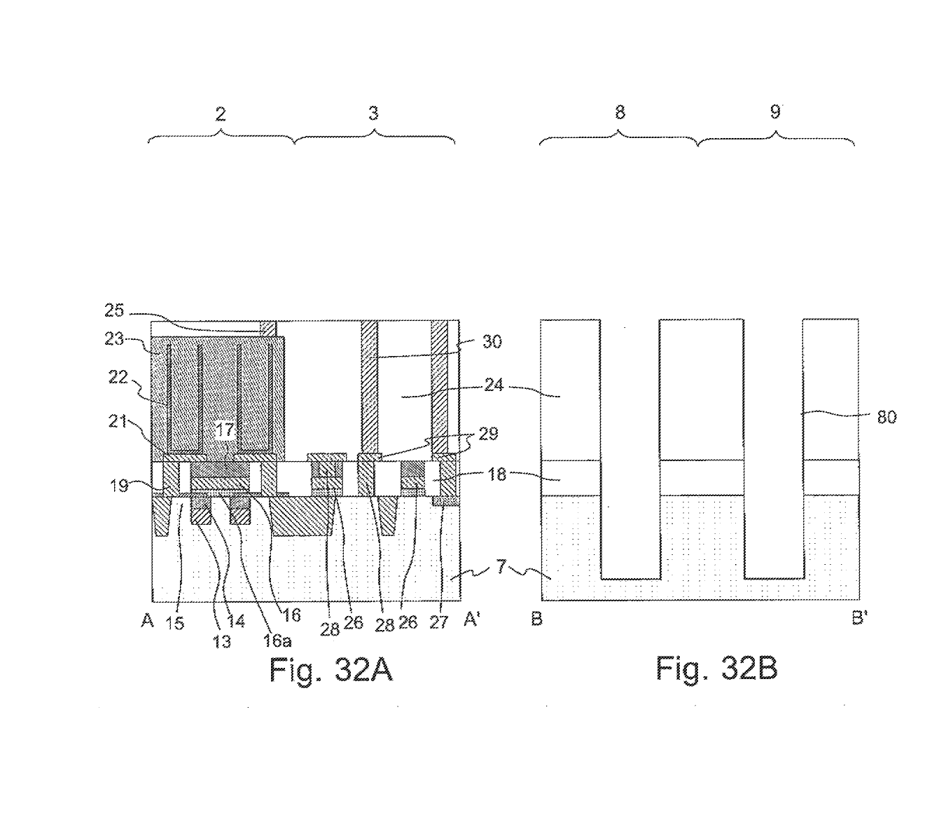

In Exemplary Embodiments 1 to 4 described above, a case is mentioned in which a rear bump (TSV) is formed from the rear surface of the semiconductor substrate. The present invention is not limited to this method, however. Alternatively, the TSV can also be formed from the front surface of the substrate. In the present exemplary embodiment, a description will be given of a TSV based on a via middle method in which the TSV is formed after a semiconductor element is formed on a surface of the semiconductor substrate. FIGS. 32A, 33A, 34A, 35A and 36A are cross-sectional process drawings corresponding to the A-A′ cross section of FIG. 3, whereas FIGS. 32B, 33B, 34B, 35B and 36B are cross-sectional process drawings corresponding to the B-B′ cross section of FIG. 3. All of the figures illustrate steps prior to substrate backgrinding. In addition, FIGS. 37 to 46 are cross-sectional process drawings corresponding to the B-B′ cross section of FIG. 3, wherein each figure illustrates a state of the substrate being held on WSS 53 and placed upside down.

First, as illustrated in FIGS. 32A and 32B, holes 80 penetrating through second interlayer insulating film 24 and first interlayer insulating film 18 and reaching to a predetermined depth of semiconductor substrate 7 are formed in sub-TSV-forming region 8 and main TSV-forming region 9, after an intermediate step in FIGS. 5A and 5B, i.e., after storage-node pad 21, capacitor 22, storage-node plate 23, and first via plug 25 are provided in memory cell region 2 in a layer of second interlayer insulating film 24, second interconnect 29 and second via plug 30 are provided in peripheral circuit region 3.

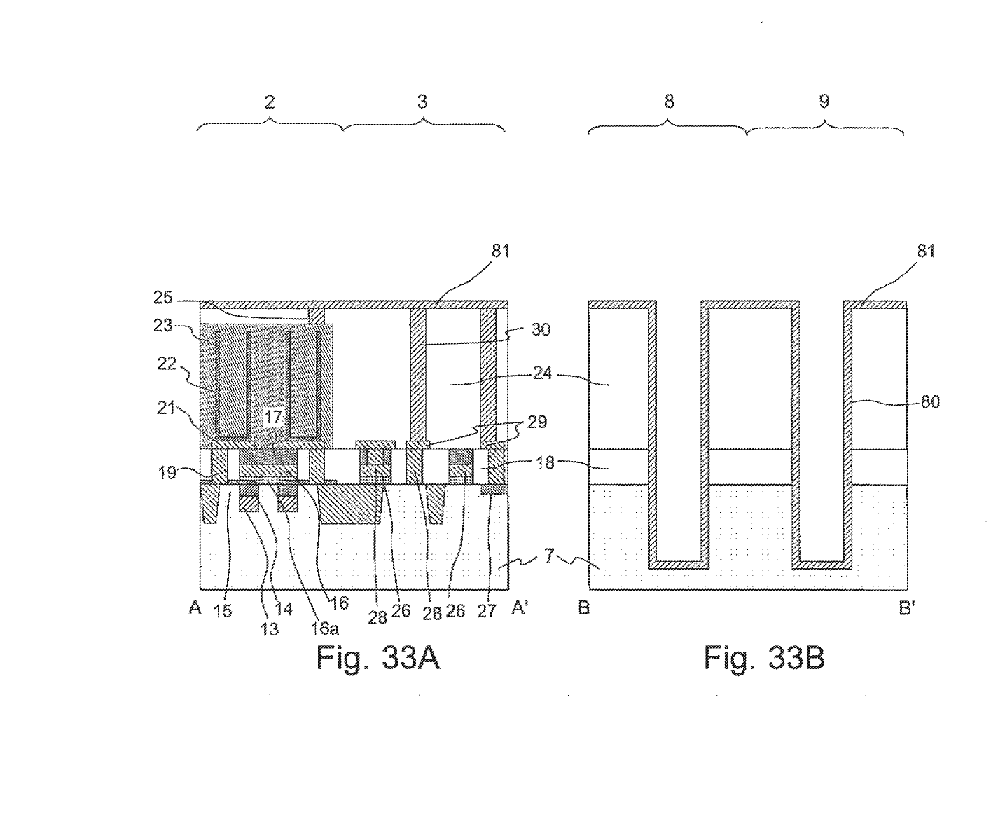

Next, as illustrated in FIGS. 33A and 33B, silicon oxide-containing insulating film 81 is formed on the entire surface of the device being fabricated.

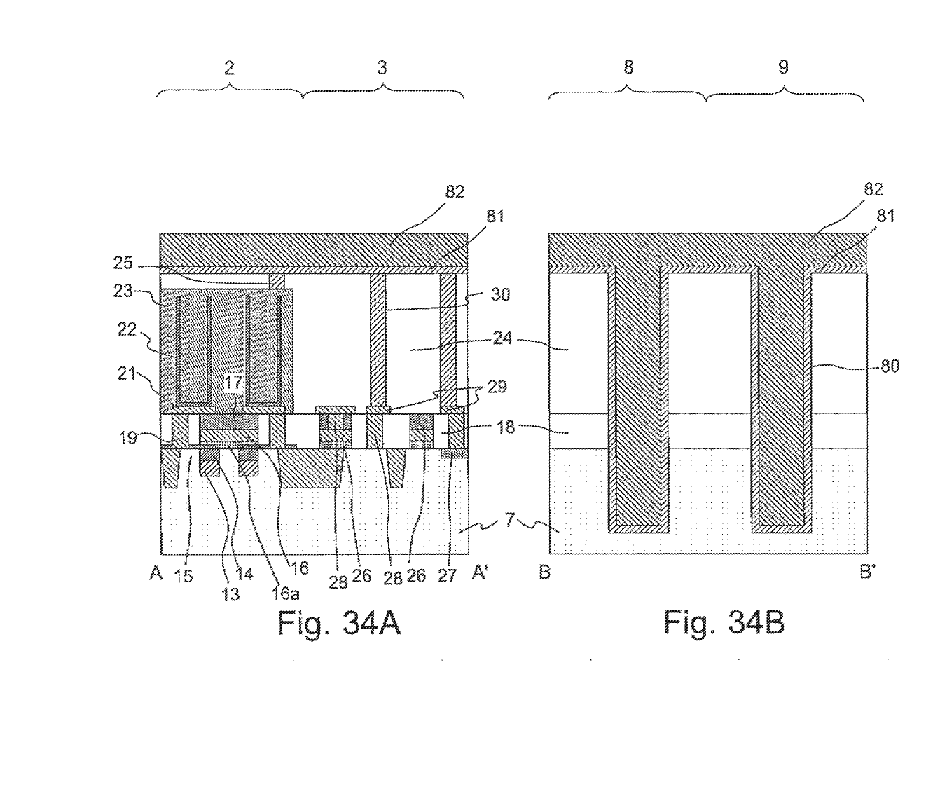

Next, as illustrated in FIGS. 34A and 34B, conductive film 82 is formed on the entire surface of the device being fabricated. As conductive film 82, a copper film may be formed by an electrolytic plating method after a feed layer is formed, as in the above-described exemplary embodiments. Alternatively, like a usual contact plug, a film of metal, such as tungsten (W), may be formed by a CVD method after a barrier film is formed.

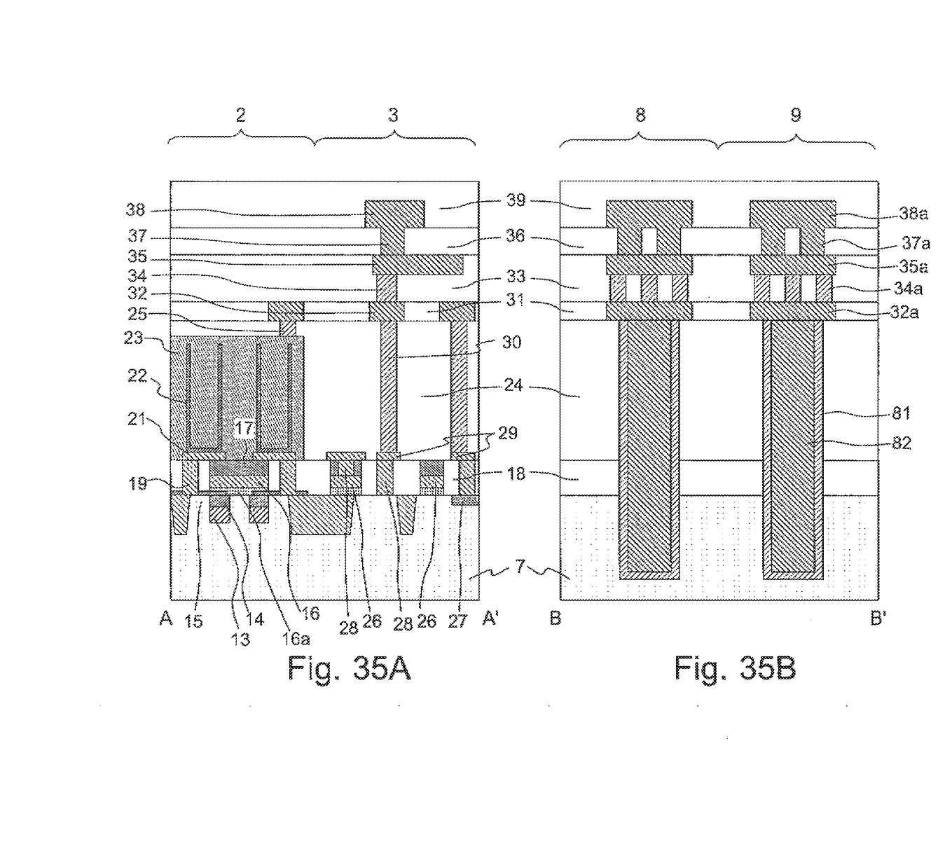

Thereafter, conductive film 82 and insulating film 81 are planarized and removed by CMP or the like, to expose first via plug 25 and second via plug 30. Note that first via plug 25 and second via plug 30 may alternatively be formed by letting the via plugs penetrate through remaining insulating film 81 and second interlayer insulating film 24 after conductive film 82 is removed. Hereafter, remaining steps among those of FIGS. 5A and 5B are carried out to form constituent elements up to protective film 39 (FIGS. 35A and 35B).

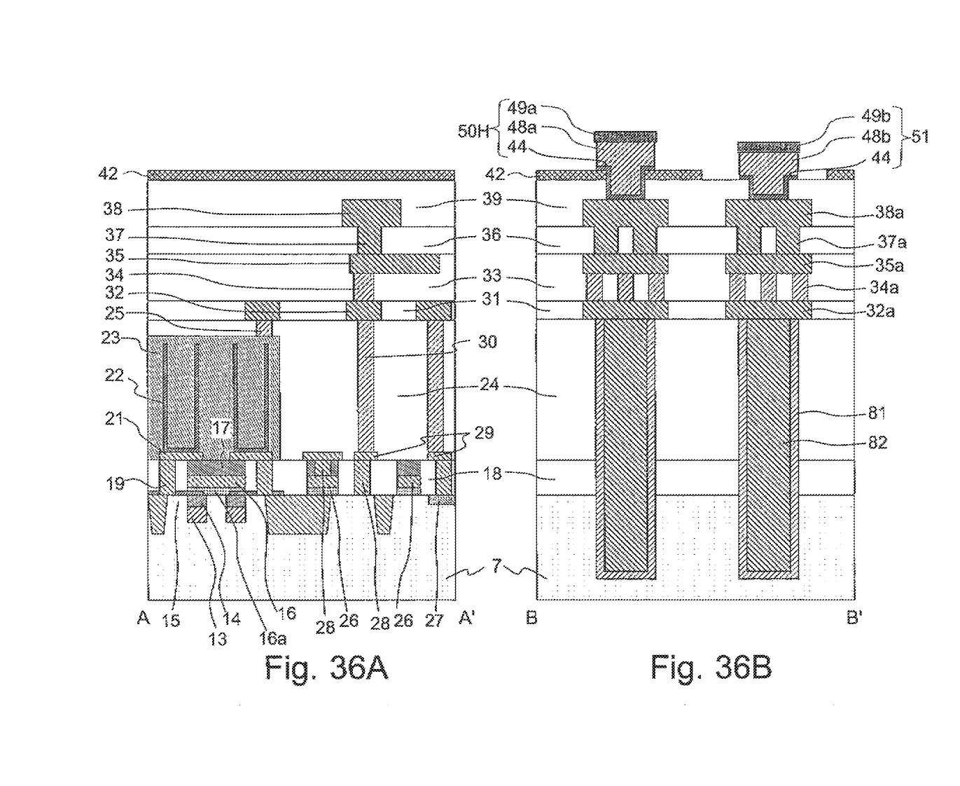

Subsequently, first main bump 51 and first sub-bump 50H made greater in height than the first main bump are formed by the method shown in Exemplary Embodiment 2 (FIGS. 36A and 36B). This completes steps on the front surface. First main bump 51 and first sub-bump 50H may be formed by the method shown in Exemplary Embodiment 4.

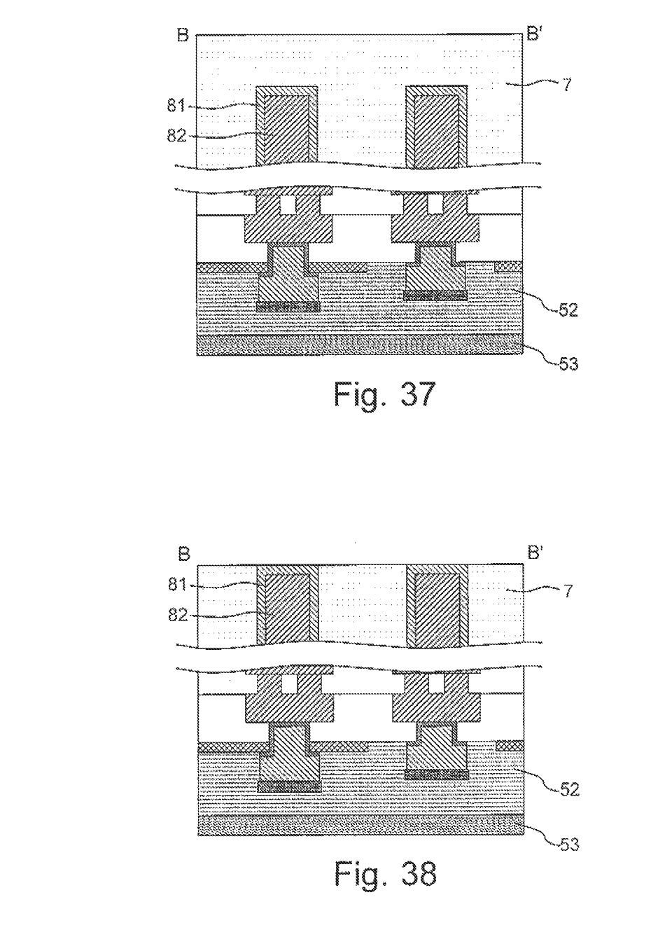

Next, the semiconductor substrate (wafer) is held on WSS 53 to grind the rear surface of the semiconductor substrate. Hereafter, figures will be shown upside down. FIG. 37 illustrates the semiconductor substrate in a state prior to backgrinding. This substrate is backside-ground by mechanical grinding until the last minute whether to expose the bottom of insulating film 81. FIG. 38 shows a state that the backside-grinding was stopped at the point of just exposing the bottom of insulating film 81. Then, the substrate is etched by silicon etch-back up to a region in which the bottom of conductive film 82 slightly protrudes from the rear surface of the substrate, as illustrated in FIG. 39.

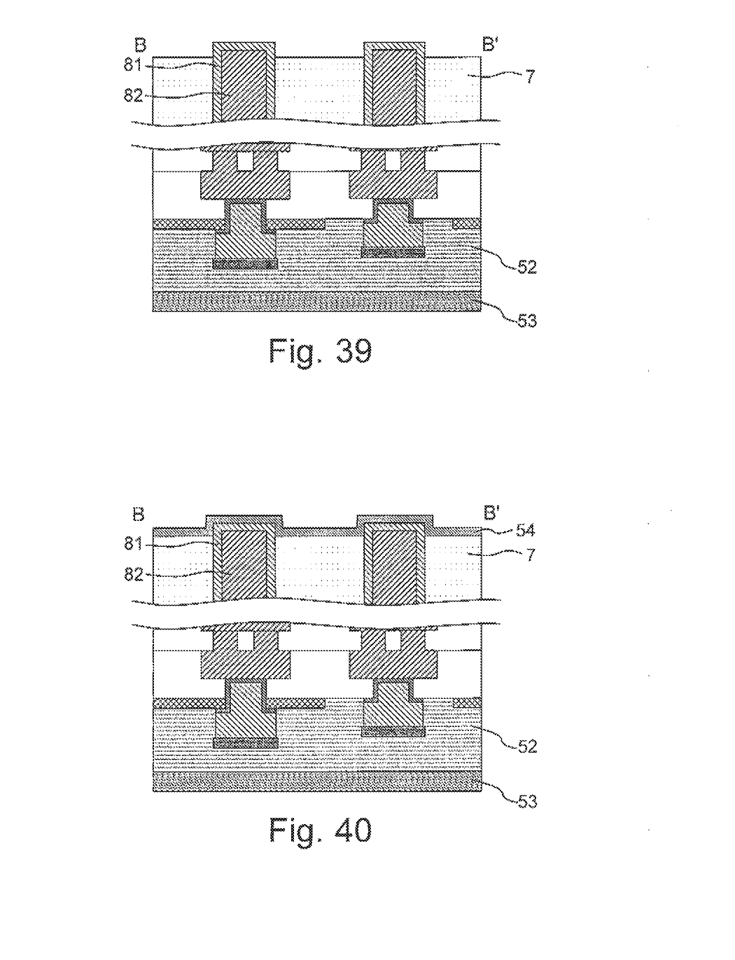

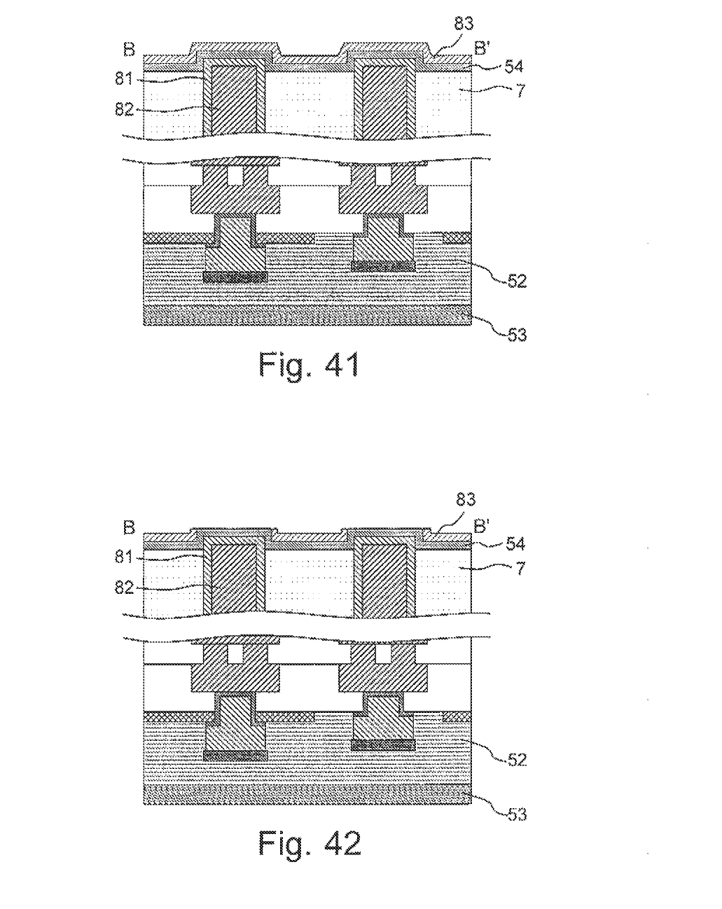

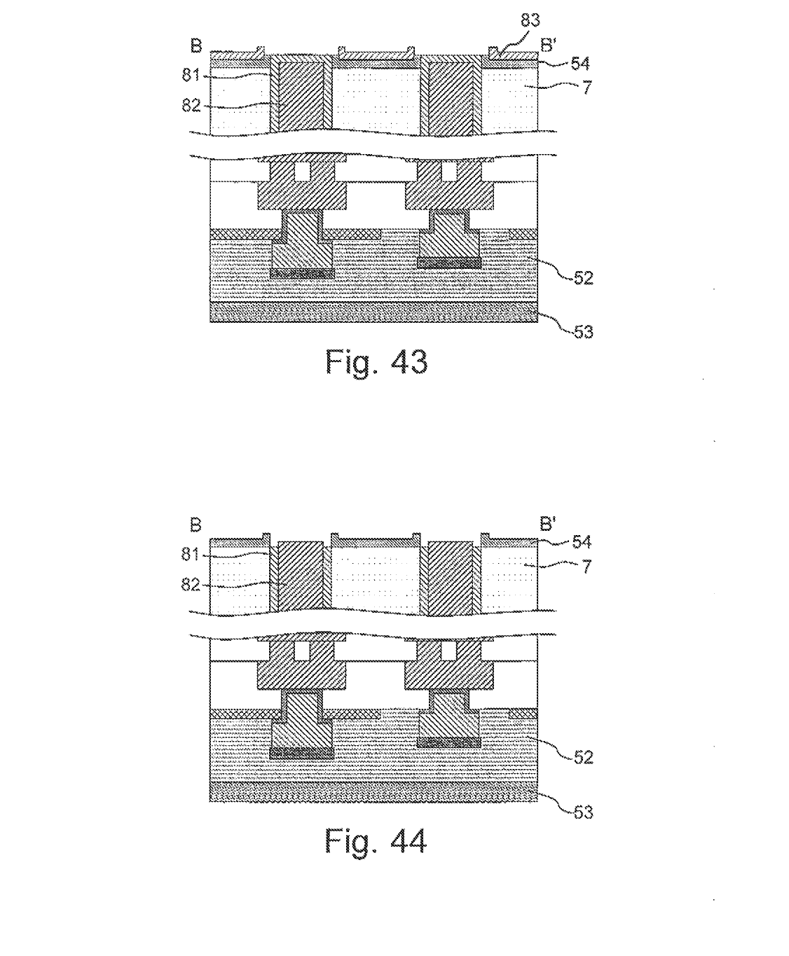

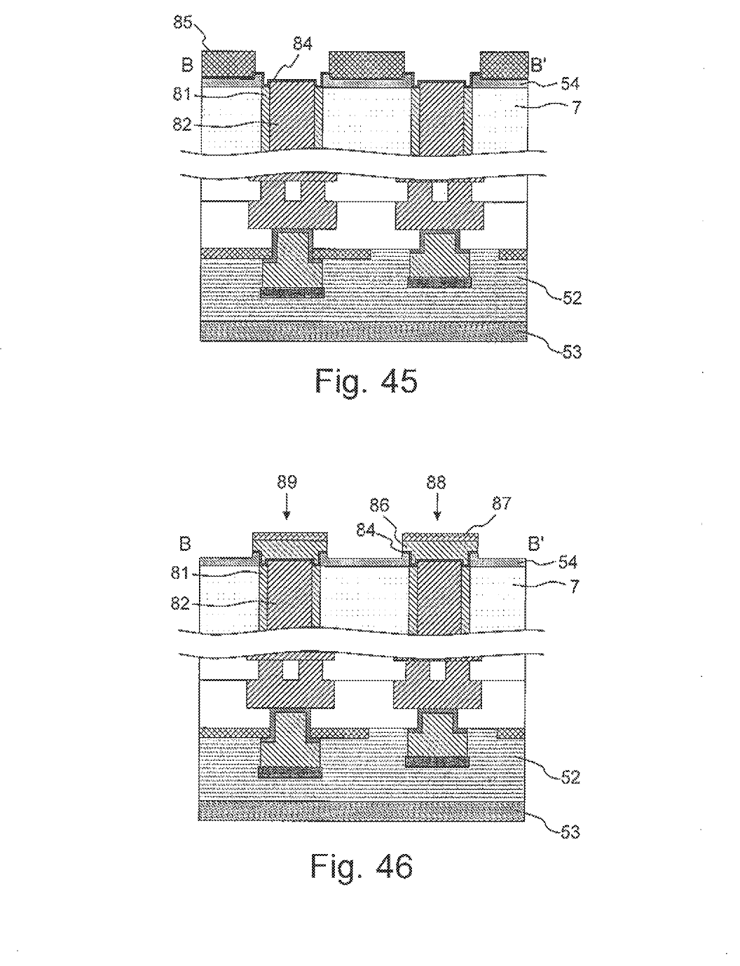

Rear-surface protective film 54 is formed on the entire rear surface (FIG. 40), and silicon oxide film 83 is further formed on the protective film (FIG. 41). Part of silicon oxide film 83 is removed by CMP or the like to expose rear-surface protective film 54 (FIG. 42). Subsequently, exposed portions of rear-surface protective film 54 are removed by wet etching or the like to expose the bottom of insulating film 81 (FIG. 43). In addition, silicon oxide film 83 and insulating film 81 are removed by oxide film etching to expose conductive film 82 (FIG. 44). At this time, a barrier film, a power-feeding film and the like are preferably removed to expose a metal film (Cu film, W film, or the like) which is a main component. Second feed layer 84 is formed on the rear surface and photoresist 85 with opening patterns are formed (FIG. 45). Finally, rear bump electrode 86 and second metal joining layer 87 are formed by electrolytic plating and then photoresist 85 and exposed second feed layer 84 are removed to form second main bump 88 and second sub-bump 89 (FIG. 46).

In the present exemplary embodiment, a case has been shown in which first main bump 51 on the front surface of the substrate and first sub-bump 50H made greater in height than the first main bump are formed. Bump formation is not limited to this method, however. Alternatively, the present exemplary embodiment may have higher second sub-bump 89 than second main bump 88 that are formed by changing opening diameters of photoresist 85 for plating in a similar manner as in Exemplary Embodiment 3. For example, the opening diameter for forming the second sub-bump can be reduced than that for forming the second main bump. It is also possible to make height variations on the front surface and the rear surface, respectively.

As described above, according to the present invention, there is no need to convexly upheave a solder layer in advance by reflow. Thus, it is also possible to simplify process steps. Needless to say, the device thus fabricated can also be used after a solder reflow treatment is performed thereon.

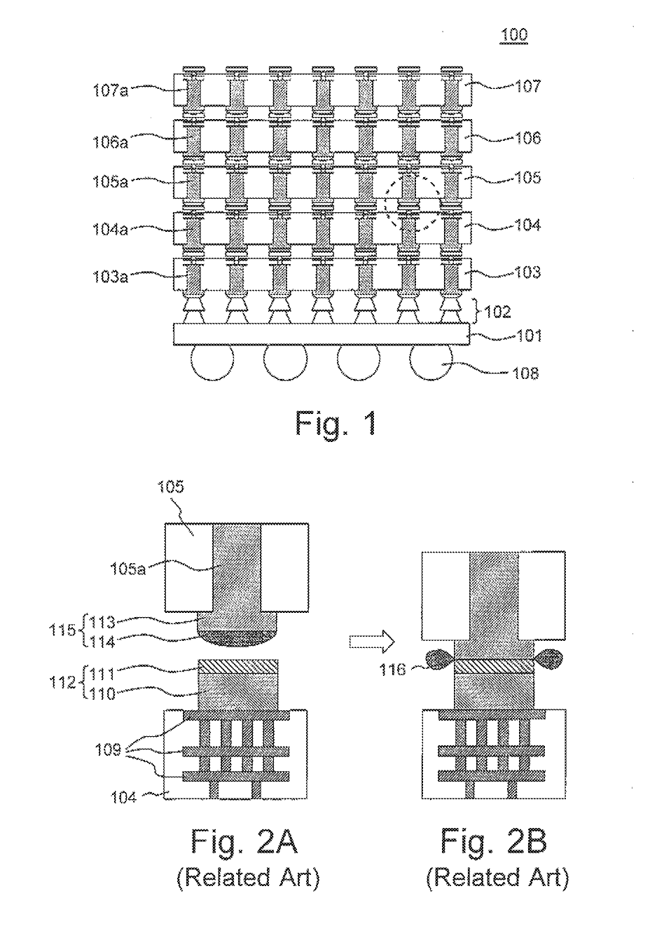

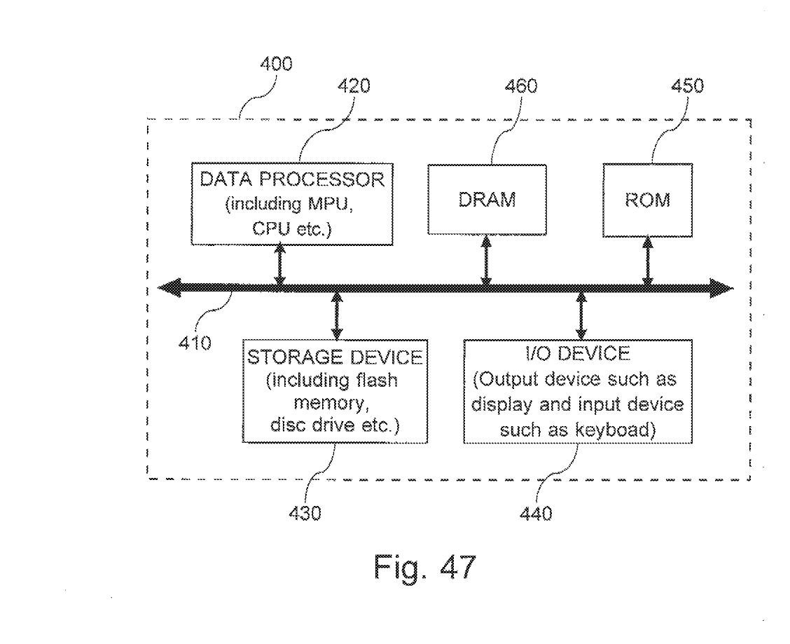

By stacking a plurality of semiconductor chips including a sub-bump greater in height than a main bump according to the present invention and, thereby, forming such a semiconductor device as illustrated in FIG. 1, it is possible to obtain a high-reliability semiconductor device. Such a semiconductor device as described above can be applied to various data processing systems. FIG. 47 illustrates one example of data processing system 400 using semiconductor devices according to the present invention. This data processing system 400 includes, for example, but not limited to, a computer system. This system 400 includes data processor 420 and DRAM 460 configured using semiconductor devices based on the present invention. Data processor 420 includes, but not limited to, a microprocessor (MPU), a digital signal processor (DPS), and the like. For the sake of simplification in FIG. 47, data processor 420 is connected to DRAM 460 mentioned above and based on the present invention through system bus 410. In some cases, however, data processor 420 is connected to DRAM 460 by a local bus, without system bus 410 being interposed therebetween.

Although only one system bus 410 is shown here for the sake of simplicity, a plurality of system buses is connected in series or parallel, as necessary, through connectors or the like. In addition, FIG. 47 illustrates an example in which storage device 430, I/O device 440, and ROM 450 are connected to system bus 410, as necessary, in this system 400. These components are not essential constituent elements, however. Here, in some cases, I/O device 440 may include a device composed only of either one of an input device and an output device. Yet additionally, the number of each component is confined to one in FIG. 47 for the sake of simplicity. The number is not limited to one, however, but this example includes a case in which at least one of the components is plural in number.

What is claimed is:

1. A semiconductor device comprising:
a substrate including a semiconductor substrate;
a first main bump and a first sub-bump formed over the substrate to protrude from a first surface of the substrate; and
a second main bump and a second sub-bump formed over the substrate to protrude from a second surface of the substrate,
the first main bump and the second main bump being electrically connected to each other through at least a plug penetrating through the semiconductor substrate, wherein
the semiconductor device has at least one of a difference between the height of the first sub-bump from the first surface of the substrate and the height of the first main bump from the first surface of the substrate and a difference between the height of the second sub-bump from the second surface of the substrate and the height of the second main bump from the second surface of the substrate.

2. The semiconductor device according to claim 1, wherein one of a pair of the first main bump and the first sub-bump and a pair of the second main bump and the second sub-bump includes a layer to be fluidized by heating as the outermost layer, and a sum of a difference between the height of the first sub-bump from the first surface of the substrate and the height of the first main bump from the first surface of the substrate and a difference between the height of the second sub-bump from the second surface of the substrate and the height of the second main bump from the second surface of the substrate is within the thickness of the layer to be fluidized on the first main bump or the second main bump.

3. The semiconductor device according to claim 1, having a difference between the height of the second sub-bump from second sub-bump from the second surface of the substrate and the height of the second main bump from the second surface of the substrate.

4. The semiconductor device according to claim 3, wherein the second sub-bump is formed integrally with a plug penetrating through the semiconductor substrate, and the diameter of the plug formed integrally with the second sub-bump is smaller than the diameter of the plug that is electrically connected to the first main bump and the second main bump and that is formed integrally with the second main bump.

5. The semiconductor device according to claim 3, wherein the diameter of a portion of the second sub-bump protruded from the second surface of the substrate is smaller than the diameter of a portion of the second main bump protruded from the second surface of the substrate.

6. The semiconductor device according to claim 1, having a difference between the height of the first sub-bump from the first surface of the substrate and the height of the second main bump from the second surface of the substrate.

7. The semiconductor device according to claim 6, including a surface protective film and a passivation film on the first surface of the substrate, wherein the first main bump includes a lower portion surrounded by the surface protective film and having a first diameter and an upper portion having a second diameter larger than the first diameter on the surface protective film, and the first sub-bump includes a lower portion formed in the surface protective film and the passivation film and having a first diameter and an upper portion having a second diameter larger than the first diameter on the passivation film.

8. The semiconductor device according to claim 6, including a front-surface protective film on the first surface of the substrate, wherein the first main bump includes a lower portion surrounded by the front-surface protective film and having a first diameter and an upper portion having a second diameter larger than the first diameter on the front-surface protective film, and the first sub-bump includes a lower portion surrounded by the front-surface protective film and having a first diameter and an upper portion having a third diameter equal to or larger than the first diameter and smaller than the second diameter on the front-surface protective film.

9. The semiconductor device according to claim 2, wherein the layer to be fluidized by heating is a solder layer.

10. The semiconductor device according to claim 9, wherein the solder layer is made of a Sn—Ag alloy.

11. The semiconductor device according to claim 2, wherein the other of the pair of the first main bump and the first sub-bump and the pair of the second main bump and the second sub-bump includes the outermost surfaces of metal.

12. A semiconductor device comprising an electrode penetrating through a substrate, the electrode including:
a main electrode provided with a first main bump protruded from a first surface of the substrate, and a second main bump protruded from a second surface of the substrate to constitute a current pathway; and
a sub-electrode provided with a first sub-bump protruded from the first surface of the substrate and a second sub-bump protruded from the second surface of the substrate,
wherein the length of the sub-electrode, including the first sub-bump and the second sub-bump, in a substrate thickness direction is greater than the length of the main electrode, including the first main bump and the second main bump.

13. The semiconductor device according to claim 12, wherein the main electrode and the sub-electrode include the first main bump and the first sub-bump connected to a first interconnect layer formed in the substrate, and, the second main bump and the second sub-bump provided with plugs penetrating through the semiconductor substrate and connected to a second interconnect layer formed in the substrate.

14. The semiconductor device according to claim 12, wherein one of a pair of the first main bump and the first sub-bump and a pair of the second main bump and the second sub-bump includes a layer to be fluidized by heating, and a sum of a difference between the height of the first sub-bump from the first surface of the substrate and the height of the first main bump from the first surface of the substrate and a difference between the height of the second sub-bump from the second surface of the substrate and the height of the second main bump from the second surface of the substrate is within the thickness of the layer to be fluidized on the first main bump or the second main bump.

15. A semiconductor device comprising:
a plurality of semiconductor chips stacked to each other,
a first main bump and a first sub-bump protruded from a first surface of each of semiconductor chips; and
a second main bump and a second sub-bump protruded from a second surface of each of the semiconductor chips, wherein
the first main bump and the second main bump being electrically connected to each other through at least a plug penetrating through a semiconductor substrate in at least the semiconductor chip provided between other semiconductor chips,
one of a pair of the first main bump and the first sub-bump of each of the semiconductor chips and a pair of the second main bump and the second sub-bump of each of the semiconductor chips includes a layer to be fluidized by heating as the outermost layer,
a sum of the height of the first main bump from the first surface of each of the semiconductor chips and the height of the second main bump from the second surface of each of the semiconductor chips is smaller than a sum of the height of the first sub-bump from the first surface of each of the semiconductor chips and the height of the second sub-bump from the second surface of each of the semiconductor chips,
at least one of the first main bumps is joined to a second main bump protruded from the second surface of another semiconductor chip at a first joint part by the layer to be fluidized by heating with little collapse, and
at least one of the first sub-bumps is joined to a second sub-bump protruded from the second surface of another semiconductor chip at a second joint part by the layer to be fluidized by heating with large collapse.

16. The semiconductor device according to claim 15, built into an information processing system.

17. The semiconductor device according to claim 15, wherein the thickness of the layer to be fluidized at the first joint part is greater than the thickness of the layer to be fluidized at the second joint part.

18. The semiconductor device according to claim 15, wherein the layer to be fluidized at the second joint part does not substantially remain on a joining face.

19. The semiconductor device according to claim 15, wherein the layer to be fluidized at the second joint part is extruded out the periphery of the second joint part.

20. The semiconductor device according to claim 15, wherein at least one of the first main bump and the second main bump joined to each other at the first joint part is connected to an interconnect layer in the uppermost layer of each of the semiconductor chips.
